(19) United States
(12) Patent Application Publication
(10) Pub. No.: US 2016/0072096 A1
(43) Pub. Date: Mar. 10, 2016

(54) SEALING FILM, METHOD FOR PRODUCING SAME AND FUNCTIONAL ELEMENT SEALED BY SEALING FILM

(71) Applicant: KONICA MINOLTA, INC., Tokyo (JP)

(72) Inventor: Yasuhiko Takamuki, Tokyo (JP)

(73) Assignee: Konica Minolta, Inc., Tokyo (JP)

(21) Appl. No.: 14/785,638

(22) PCT Filed: Apr. 1, 2014
(86) PCT No.: PCT/JP2014/059623

§ 371 Date: Oct. 20, 2015

(30) Foreign Application Priority Data
Apr. 30, 2013 (JP) 2013-094926

(51) Int. Cl. H01L 51/52; H01L 31/048

(52) U.S. Cl. CPC H01L 51/5253; H01L 31/0481

(57) ABSTRACT

A method for producing a sealing film includes forming a first gas barrier layer on a surface of a substrate by applying an application liquid including a polysilazane, drying the application liquid, and performing a modification treatment. The method further includes forming a resin layer by applying a resin layer liquid comprising an ionic liquid onto the first gas barrier layer and drying the resin layer liquid.

### TECHNICAL FIELD

One or more embodiments of the present invention relate to a sealing film, a method for producing the sealing film, and a functional element sealed by the sealing film. More specifically, one or more embodiments of the present invention relate to a sealing film that is excellent in resistance to moisture permeation even when used after having been stored in a high humidity environment, a method for producing the sealing film, and a functional element sealed by the sealing film such as an organic electroluminescent element or a solar battery element.

### BACKGROUND ART

In flexible electronic devices such as an organic electroluminescent element (hereinafter also simply referred to as an organic EL element) and a solar battery element having flexibility, a very high gas barrier property at a glass substrate level is required. Therefore, under the current situation, a gas barrier film having a sufficient gas barrier performance has not been obtained yet.

Functional elements formed of an organic material such as an organic EL element and an organic thin film solar battery have extremely low resistance against oxygen and moisture. For example, in the case when a display or an illumination device is constituted by using an organic EL element, there is a disadvantage that the organic material itself is altered by oxygen or moisture, and thus the luminance decreases, a non-luminescent defect called as a dark spot generates, and eventually the EL element does not emit light.

Accordingly, a sealing technique that provides an excellent blocking property against oxygen and water vapor by a sealing structure in which a substrate having an organic EL element formed on one surface is attached together with a resin composition layer and a sealing substrate so as to cover the entire surface of the organic EL element (hereinafter this sealing structure is referred to as “solid sealing”) is known (for example, see Patent Literatures 1 and 2).

In the above-mentioned technique, a sealing film composed of a substrate and an adhesive resin is used, but the sealing film is used little immediately after production, and is generally used after storage for several days to several months. However, it was proved that, when the sealing film is used after storage specifically under a high humidity environment, the resistance to moisture permeation is deteriorated, and when the sealing film after the storage is used as a sealing substrate for an organic EL element, the above-mentioned dark spot is easily generated.

### CITATION LIST

### Patent Literatures

Patent Literature 1: WO 2011/016408 A

Patent Literature 2: WO 2011/102465 A

### SUMMARY OF INVENTION

One or more embodiments of the present invention were made to provide a sealing film that is excellent in resistance to moisture permeation even when used after having been stored in a high humidity environment, a method for producing the sealing film, and a functional element sealed by the sealing film.

The present inventors found that a sealing film that is excellent in resistance to moisture permeation even when used after having been stored in a high humidity environment can be obtained by further forming a resin layer containing at least an ionic liquid, on a sealing film having a gas barrier layer that has been formed by subjecting a layer that has been formed by applying an application liquid containing at least a polysilazane and drying the application liquid to a modification treatment.

One or more embodiments of the present invention are exemplified below.

1. A sealing film including a substrate, and a gas barrier layer and a resin layer that have been formed on one surface of the substrate, in this order, wherein the gas barrier layer is a layer formed by applying an application liquid containing at least a polysilazane and drying the application liquid, and subjecting the product to a modification treatment, and the resin layer contains at least an ionic liquid.

2. The sealing film according to Item. 1, wherein the gas barrier layer further contains an aluminum compound.

3. The sealing film according to Item. 1 or 2, wherein the ionic liquid contained in the resin layer is constituted by at least an ammonium-based cation or a phosphonium-based cation and an N-acylamino acid ion or a carboxylic acid-based anion.

4. The sealing film according to any one of Items. 1 to 3, wherein a gas barrier layer has been further formed between the substrate and the gas barrier layer by a discharging plasma chemical vapor deposition process having a discharging space between a pair of rollers to which an electric field has been applied, by using a raw material gas containing an organic silicon compound and an oxygen gas on the surface of the substrate.

5. A method for producing a sealing film including a substrate, and a gas barrier layer and a resin layer that have been formed on one surface of the substrate, in this order, including: a step of forming a gas barrier layer by subjecting a layer that has been formed by applying an application liquid containing at least a polysilazane and drying the application liquid, to a modification treatment; and a step of forming a resin layer by applying a resin layer liquid containing at least an ionic liquid onto the gas barrier layer and drying the resin layer liquid.

6. A functional element that has been sealed with the sealing film according to any one of Items. 1 to 4.

As explained in Items 1-6 listed above, a sealing film that is excellent in resistance to moisture permeation even when used after having been stored in a high humidity environment, a method for producing the sealing film, and a functional element sealed by the sealing film can be provided.

The mechanism of expression of the effect or the mechanism of action of one or more embodiments of the present invention has not been clarified, and is conjectured as follows.

It is considered that, in the storage of a sealing film, the side of an adhesive resin that is in contact with an organic EL element is directly brought into contact with the atmospheric air and adsorbs moisture, and the moisture vaporizes by being heated during solid sealing, whereby the element is deteriorated to generate dark spots, and the moisture that remains without being vaporized also causes the deterioration of the resistance to moisture permeation in the subsequent storage over time.

When a water absorbing layer is disposed on the sealing film, the water absorber contained in the water absorbing layer absorbs the above-mentioned moisture, and thus the effect of the moisture on the organic EL element is improved, but the effect was insufficient in the scopes of the technologies of the known documents.

Although the mechanism of maintaining the resistance to moisture permeation even under a high humidity environment in the sealing film having the constitution of one or more embodiments of the present invention is unclear, it is presumed that the ionic liquid contained in the resin layer formed on the sealing film absorbs the above-mentioned moisture like a water absorber and also has an ability to supply the moisture to the polysilazane in the unmodified part remaining in the gas barrier layer, and the unmodified part in the polysilazane reacts with the moisture and is modified, whereby a gas barrier film having a high resistance to moisture permeation, which is closer to a glass, is formed.

### BRIEF DESCRIPTION OF DRAWINGS

FIG. 1 is a cross-sectional view of the sealing film in accordance with one or more embodiments of the present invention.

FIG. 2 is a schematic drawing showing an example of a vacuum plasma CVD device used in the formation of the gas barrier layer in accordance with one or more embodiments of the present invention.

FIG. 3 is a cross-sectional view showing a schematic constitution of the organic EL element.

FIG. 4 is a schematic drawing showing an example of a vacuum UV irradiation device.

### DESCRIPTION OF EMBODIMENTS

The sealing film of one or more embodiments of the present invention is characterized by being a sealing film including a substrate, and a gas barrier layer and a resin layer that have been formed on one surface of the substrate, in this order, wherein the gas barrier layer is a layer that has been formed by applying an application liquid containing at least a polysilazane and drying the application liquid, and subjecting the product to a modification treatment, and the resin layer contains at least an ionic liquid, and provides a sealing film that is excellent in resistance to moisture permeation even when used after having been stored in a high humidity environment by such constitution. This characteristic is a technical feature that is common among one or more embodiments of the invention as described in Items 1 to 6 above.

In one or more embodiments of the present invention, in view of exertion of the effect of one or more embodiments of the present invention, the above-mentioned gas barrier layer may further contain an aluminum compound, and the ionic liquid contained in the above-mentioned resin layer may be constituted by at least an ammonium-based cation or a phosphonium-based cation, and an N-acylamino acid ion or a carboxylic acid-based anion. By the above-mentioned constitution, a sealing film in which the resistance to moisture permeation has been further improved can be obtained.

Furthermore, a gas barrier layer may have been further formed between the substrate and the gas barrier layer by a discharging plasma chemical vapor deposition process having a discharging space between a pair of rollers to which an electric field has been applied, by using a raw material gas containing an organic silicon compound and an oxygen gas on the surface of the substrate, from the viewpoint that the flexibility and gas barrier property of the sealing film are further improved.

The method for producing a sealing film according to one or more embodiments of the present invention may be conducted by a step of forming a gas barrier layer by subjecting a layer that has been formed by applying an application liquid containing at least a polysilazane and drying the application liquid to a modification treatment, and a step of forming a resin layer by applying a resin layer liquid containing at least an ionic liquid onto the gas barrier layer and drying the resin layer liquid.

Furthermore, a functional element sealed with the sealing film of one or more embodiments of the present invention is preferable, since, for example, a stable organic EL element in which generation of dark spots and decrease of the luminance have been suppressed over time can be obtained.

One or more embodiments for carrying out the present invention will be explained below in detail. In the present application, “to” is used for meaning that the numerical values described before and after the term are included as a lower limit value and an upper limit value.

<Summary of Sealing Film>

The sealing film of one or more embodiments of the present invention is characterized by being a sealing film including a substrate, and a gas barrier layer and a resin layer that have been formed on one surface of the substrate, in this order, wherein the gas barrier layer is a layer formed by applying an application liquid containing at least a polysilazane and drying the application liquid, and subjecting the product to a modification treatment, and the resin layer contains at least an ionic liquid.

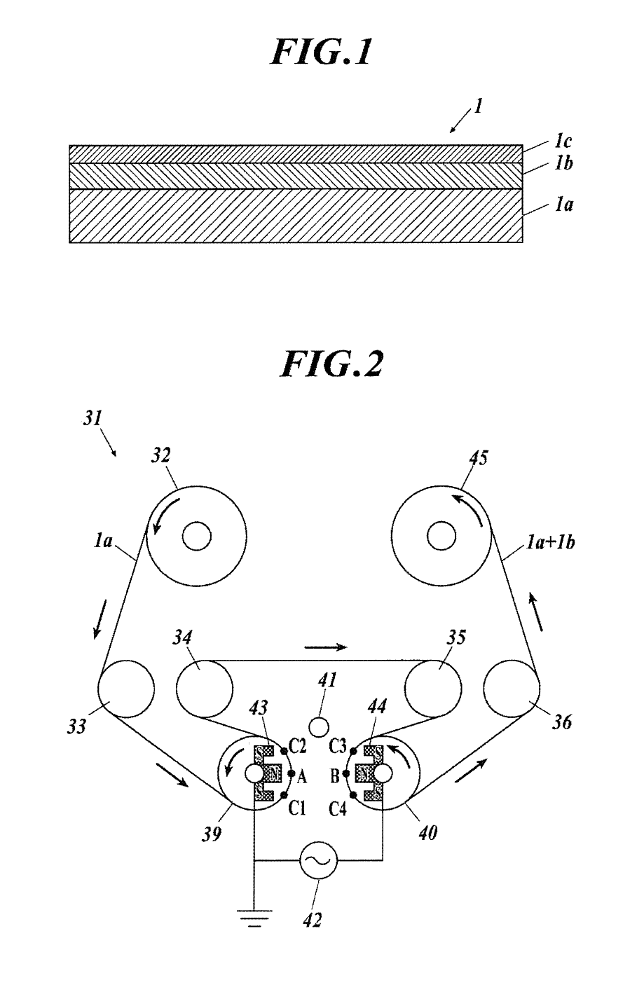

FIG. 1 shows a cross-sectional view showing an example of the sealing film of one or more embodiments of the present invention.

The sealing film 1 of one or more embodiments of the present invention is such that at least a substrate 1a, a gas barrier layer 1b and a resin layer 1c are formed in this order. Hereinafter the form in which the gas barrier layer 1b is formed on the substrate 1a will also be referred to as a gas barrier film.

Other layers can be formed on the surface on the side opposite to the gas barrier layer of the substrate 1a, between the substrate 1a and the gas barrier layer 1b, between the gas barrier layer 1b and the resin layer 1c, and on the surface on the side opposite to the gas barrier layer of the resin layer 1c, to the extent that the effect of one or more embodiments of the present invention is not deteriorated. For example, it is possible to dispose a smoothing layer between the substrate 1a and the gas barrier layer 1b to smoothen the unevenness of the substrate surface, or to provide a layer such as a peelable separator film on the surface on the side opposite to the gas barrier layer of the resin layer 1c. Furthermore, examples of the other layer include functional layers such as an intermediate layer, a protective layer, a bleed-out prevention layer and an antistatic layer, and the like.

Furthermore, the gas barrier layer 1b and the resin layer 1c in one or more embodiments of the present invention may be formed of a plurality of layers, and the gas barrier layer may be formed of a form in which plural barrier layers are stacked.

Firstly, the resin layer containing at least an ionic liquid, which is a characteristic of one or more embodiments of the present invention, will be explained.

<<Resin Layer>>

The resin layer in one or more embodiments of the present invention is a layer containing at least an ionic liquid, and may be a layer that contains at least a thermal curable resin together with the ionic liquid, and has a function as an adhesive layer in sealing a functional element.

The resin layer may contain, besides the thermal curable resin, a hygroscopic metal oxide, an inorganic filler and a curing accelerator, and the like, in view of resistance to moisture permeation.

[Ionic Liquid]

The ionic liquid in one or more embodiments of the present invention is a salt that may be molten at a temperature region of 140° C. or less (preferably 120° C. or less). The ionic liquid may have a function to absorb moisture like a hygroscopic agent, and also has an ability to supply the moisture to the polysilazane in the unreacted part remaining in the gas barrier layer to thereby contribute to the modification of the unreacted part of the polysilazane.

As the ionic liquid, for example, a salt having an activity to allow the curing of an epoxy resin, which is a thermal curable resin mentioned below, may be used, and the salt advantageously acts on the improvement of the resistance to moisture permeation of the cured product of the resin layer. The ionic liquid may be used in the state that the ionic liquid is homogeneously dissolved in the above-mentioned epoxy resin.

Examples of the cation that constitutes such ionic liquid include ammonium-based cations such as imidazolium ion, pyrimidinium ion, pyridinium ion, pyrrolidinium ion, piperidinium ion, pyrazonium ion and guanidium ion; phosphonium-based cations such as tetraalkylphosphonium cations (for example, tetrabutylphosphonium ion, tributylhexylphosphonium ion and the like); sulfonium-based cations such as triethylsulfonium ion, and the like.

Specific examples of the ammonium-based cation include 1,3-dimethylimidazolium cation, 1,3-diethylimidazolium cation, 1-ethyl-3-methylimidazolium cation, 1-propyl-3-methylimidazolium ion, 1-butyl-3-methylimidazolium cation, 1-hexyl-3-methylimidazolium cation, 1-octyl-3-methylimidazolium cation, 1-decyl-3-methylimidazolium cation, 1-dodecyl-3-methylimidazolium cation, 1-tetradecyl-3-methylimidazolium cation, 1,2-dimethyl-3-propylimidazolium cation, 1-ethyl-2,3-dimethylimidazolium cation, 1-butyl-2,3-dimethylimidazolium cation, 1-hexyl-2,3-dimethylimidazolium cation, 1,3-dimethyl-1,4,5,6-tetrahydropyrimidinium cation, 1,2,3-trimethyl-1,4,5,6-tetrahydropyrimidinium cation, 1,2,3,4-tetramethyl-1,4,5,6-tetrahydropyrimidinium cation, 1,2,3,5-tetramethyl-1,4,5,6-tetrahydropyrimidinium cation, 1,3-dimethyl-1,4-dihydropyrimidinium cation, 1,3-dimethyl-1,6-dihydropyrimidinium cation, 1,2,3-trimethyl-1,4-dihydropyrimidinium cation, 1,2,3-trimethyl-1,6-dihydropyrimidinium cation, 1,2,3,4-tetramethyl-1,4-dihydropyridinium cation, 1,2,3,4-tetramethyl-1,6-dihydropyrimidinium cation, 1-ethylpyridinium cation, 1-butylpyridinium cation, 1-hexylpyridinium cation, 1-butyl-3-methylpyridinium cation, 1-butyl-4-methylpyridinium cation, 1-hexyl-3-methylpyridinium cation, 1-butyl-3,4-dimethylpyridinium cation, 1,1-dimethylpyrrolidinium cation, 1-ethyl-1-methylpyrrolidinium cation, 1-methyl-1-propylpyrrolidinium cation, 1-methyl-1-butylpyrrolidinium cation, 1-methyl-1-pentylpyrrolidinium cation, 1-methyl-1-hexylpyrrolidinium cation, 1-methyl-1-heptylpyrrolidinium cation, 1-ethyl-1-propylpyrrolidinium cation, 1-ethyl-1-butylpyrrolidinium cation, 1-ethyl-1-pentylpyrrolidinium cation, 1-ethyl-1-hexylpyrrolidinium cation, 1-ethyl-1-heptylpyrrolidinium cation, 1,1-dipropylpyrrolidinium cation, 1-propyl-1-butylpyrrolidinium cation, 1,1-dibutylpyrrolidinium cation, 1-propylpiperidinium cation, 1-pentylpiperidinium cation, 1,1-dimethylpiperidinium cation, 1-methyl-1-ethylpiperidinium cation, 1-methyl-1-propylpiperidinium cation, 1-methyl-1-butylpiperidinium cation, 1-methyl-1-pentylpiperidinium cation, 1-methyl-1-hexylpiperidinium cation, 1-methyl-1-heptylpiperidinium cation, 1-ethyl-1-propylpiperidinium cation, 1-ethyl-1-butylpiperidinium cation, 1-ethyl-1-pentylpiperidinium cation, 1-ethyl-1-hexylpiperidinium cation, 1-ethyl-1-heptylpiperidinium cation, 1,1-dipropylpiperidinium cation, 1-propyl-1-butylpiperidinium cation, 1,1-dibutylpiperidinium cation, 1-methylpyrazolium cation, 3-methylpyrazolium cation, 1-ethyl-2-methylpyrazolinium cation, 1-ethyl-2,3,5-trimethylpyrazolium cation, 1-propyl-2,3,5-trimethylpyrazolium cation, 1-butyl-2,3,5-trimethylpyrazolium cation, 1-ethyl-2,3,5-trimethylpyrazolinium cation, 1-propyl-2,3,5-trimethylpyrazolinium cation, 1-butyl-2,3,5-trimethylpyrazolinium cation and the like.

Among the above-mentioned cations, the ammonium-based cations and phosphonium-based cations are preferable, and imidazolium ion and phosphonium ion are more preferable.

Furthermore, examples of the anion that constitutes such ionic liquid include halide-based anions such as fluoride ion, chloride ion, bromide ion and iodide ion; alkylsulfuric acid-based anions such as methanesulfonate ion; fluorine-containing compound-based anions such as trifluoromethanesulfonate ion, hexafluorophosphonate ion, trifluorotris(pentafluoroethyl)phosphonate ion, bis(trifluoromethanesulfonyl)imide ion, trifluoroacetate ion and tetrafluoroborate ion; phenol-based anions such as phenol ion, 2-methoxyphenol ion and 2,6-di-tert-butylphenol ion; acidic amino acid ions such as aspartate ion and glutamate ion; neutral amino acid ions such as glycine ion, alanine ion and phenylalanine ion; N-acylamino acid ions represented by the following general formula (1) such as N-benzoylalanine ion, N-acetylphenylalanine ion and N-acetylglycine ion; carboxylic acid-based anions such as formate ion, acetate ion, decanate ion, 2-pyrrolidone-5-carboxylate ion, α-lipoate ion, lactate ion, tartrate ion, hippurate ion, N-methylhippurate ion and benzoate ion.

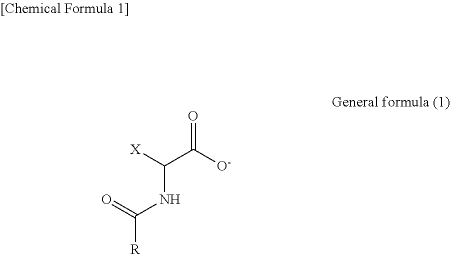

wherein R—CO— is an acyl group derived from a straight chain or branched chain aliphatic acid having a carbon number of from 1 to 5, or a substituted or unsubstituted benzoyl group, and —NH—CHX—CO₂⁻ is an ion of an acidic amino acid such as asparagine acid or glutamic acid, or an ion of a neutral amino acid such as glycine, alanine or phenylalanine.

Furthermore, the anion is preferably an N-acylamino acid ion represented by the general formula (1) or a carboxylic acid-based anion.

Specific examples of the carboxylic acid-based anion include acetate ion, decanate ion, 2-pyrrolidone-5-carboxylate ion, formate ion, α-lipoate ion, lactate ion, tartrate ion, hippurate ion, N-methylhippurate ion and the like, and among these, acetate ion, 2-pyrrolidone-5-carboxylate ion, formate ion, lactate ion, tartrate ion, hippurate ion and N-methylhippurate ion are preferable, and acetate ion, N-methylhippurate ion and formate ion are more preferable. Furthermore, specific examples of the N-acylamino acid ion represented by the general formula (1) include N-benzoylalanine ion, N-acetylphenylalanine ion, aspartate ion, glycine ion, N-acetylglycine ion and the like, and among these, N-benzoylalanine ion, N-acetylphenylalanine ion and N-acetylglycine ion are preferable, and N-acetylglycine ion is more preferable.

As specific ionic liquids, for example, 1-butyl-3-methylimidazolium lactate, tetrabutylphosphonium-2-pyrrolidone-5-carboxylate, tetrabutylphosphonium acetate, tetrabutylphosphonium decanoate, tetrabutylphosphonium trifluoroacetate, tetrabutylphosphonium α-lipoate, tetrabutylphosphonium formate salt, tetrabutylphosphonium lactate, bis(tetrabutylphosphonium)tartrate salt, tetrabutylphosphonium hippurate salt, tetrabutylphosphonium N-methylhippurate salt, tetrabutylphosphonium benzoyl-DL-alanine salt, tetrabutylphosphonium N-acetylphenylalanine salt, tetrabutylphosphonium 2,6-di-tert-butylphenol salt, monotetrabutylphosphonium L-aspartate salt, tetrabutylphosphonium glycine salt, tetrabutylphosphonium N-acetylglycine salt, 1-ethyl-3-methylimidazolium lactate, 1-ethyl-3-methylimidazolium acetate, 1-ethyl-3-methylimidazolium formate salt, 1-ethyl-3-methylimidazolium hippurate salt, 1-ethyl-3-methylimidazolium N-methylhippurate salt, bis(1-ethyl-3-methylimidazolium)tartrate salt, 1-ethyl-3-methylimidazolium N-acetylglycine salt are preferable, and tetrabutylphosphonium N-acetylglycine salt, 1-ethyl-3-methylimidazolium acetate, 1-ethyl-3-methylimidazolium formate salt, 1-ethyl-3-methylimidazolium hippurate salt and 1-ethyl-3-methylimidazolium N-methylhippurate salt are more preferable.

Examples of the method for synthesizing the above-mentioned ionic liquid include, but are not limited to, an anion exchange method in which a precursor constituted by a cation site such as an alkylimidazolium, an alkylpyridinium, an alkylammonium and an alkylsulfonium ion and an anion site containing a halogen is reacted with NaBF₄, NaPF₆, CF₃SO₃Na, LiN(SO₂CF₃)₂ or the like, an acid ester method in which an organic acid residue becomes an anion while an alkyl group is introduced by reacting an amine-based substance and an acid ester, and a neutralization method in which an amine is neutralized with an organic acid to give a salt, and the like. In the neutralization method by an anion, a cation and a solvent, it is possible to use the anion and cation in equivalent amounts, distill off the solvent in the obtained reaction liquid and use the product as it is, or liquid concentration may further be conducted by adding an organic solvent (methanol, toluene, ethyl acetate, acetone or the like).

The content of the ionic liquid in one or more embodiments of the present invention is preferably in the range of from 0.1 to 50% by mass, more preferably in the range of from 0.5 to 25% by mass with respect to the entirety of the resin layer. In this range, the effect of one or more embodiments of the present invention can be more sufficiently obtained, and the storage stability of the resin layer is not deteriorated.

[Thermal Curable Resin]

The resin contained in the resin layer is preferably a thermal curable resin, and the thermoplastic resin is not specifically limited, and specific examples include various thermal curable resins such as epoxy resins, cyanate ester resins, phenolic resins, bismaleimide-triazine resins, polyimide resins, acrylic resins and vinylbenzyl resins. Among these, epoxy resins are preferable in view of low temperature curability, adhesiveness and the like.

The epoxy resins maybe any ones having two or more epoxy groups in average per one molecule, and specific examples include bisphenol A-type epoxy resins, biphenyl-type epoxy resins, biphenylaralkyl-type epoxy resins, naphthol-type epoxy resins, naphthalene-type epoxy resins, bisphenol F-type epoxy resins, phosphorus-containing epoxy resins, bisphenol S-type epoxy resins, aromatic glycidylamine-type epoxy resins (specifically tetraglycidyldiaminodiphenylmethane, triglycidyl-p-aminophenol, diglycidyltoluidine, diglycidylaniline and the like), alicyclic epoxy resins, aliphatic chain epoxy resins, phenol novolak-type epoxy resins, cresol novolak-type epoxy resins, bisphenol A novolak-type epoxy resins, epoxy resins having a butadiene structure, phenolaralkyl-type epoxy resins, epoxy resins having a dicyclopentadiene structure, diglycidyl-etherified products of bisphenols, diglycidyl-etherified products of naphthalenediol, glycidyl-etherified products of phenols and diglycidyl-etherified products of alcohols, and alkyl-substituted forms, halides and hydrogenated products of these epoxy resins, and the like. These may be used by one kind, or in combination of two or more kinds.

Among these, bisphenol A-type epoxy resins, bisphenol F-type epoxy resins, phenol novolak-type epoxy resins, biphenylaralkyl-type epoxy resins, phenolaralkyl-type epoxy resins, aromatic glycidylamine-type epoxy resins, epoxy resins having a dicyclopentadiene structure, and the like are preferable in view of keeping the high heat-resistance and low moisture permeability of the resin composition.

Furthermore, the epoxy resin may be either a liquid or a solid form, or both a liquid and a solid form may be used. The “liquid” and “solid form” used herein are the states of the epoxy resin at 25° C. In view of coating property, processability, adhesiveness and the like, 10% by mass or more of the entirety of the used epoxy resin may be a liquid.

Furthermore, the epoxy resin has an epoxy equivalent amount of preferably in the range of from 100 to 1,000, more preferably in the range of from 120 to 1,000 in view of reactivity. The epoxy equivalent amount as used herein is a gram number of a resin containing 1 g equivalent amount of epoxy groups (g/eq), and is measured according to the method described in JIS K-7236.

The curing agent for the epoxy resin is not specifically limited as long as it has a function to allow the curing of the epoxy resin, but from the viewpoint of suppressing the thermal deterioration of the element (specifically the organic EL element) during the curing treatment of the resin composition, the curing treatment of the resin composition is preferably conducted at preferably 140° C. or less, more preferably at 120° C. or less, and the curing agent is preferably a curing agent having an action to cure the epoxy resin at such temperature region.

Specific examples include primary amine, secondary amine, tertiary amine-based curing agents, polyaminoamide-based curing agents, dicyandiamides, organic acid dihydrazides and the like, and among these, amine adduct-based compounds (Amicure PN-23, Amicure MY-24, Amicure PN-D, Amicure MY-D, Amicure PN—H, Amicure MY-H, Amicure PN-31, Amicure PN-40, Amicure PN-40J and the like (all of these are manufactured by Ajinomoto Fine-Techno Co., Inc.)), organic acid dihydrazides (Amicure VDH-J, Amicure UDH, Amicure LDH and the like (all of these are manufactured by Ajinomoto Fine-Techno Co., Inc.)) and the like are preferable in view of rapid curability. These may be used by one kind, or in combination of two or more kinds.

[Hygroscopic Metal Oxide]

The resin layer in one or more embodiments of the present invention may contain a hygroscopic metal oxide from the viewpoint of adjustment of the moisture permeability.

The “hygroscopic metal oxide” as referred to in one or more embodiments of the present invention means a metal oxide that has an ability to absorb moisture and chemically reacts with absorbed moisture to become a hydroxide, and is not specifically limited as long as the purpose of one or more embodiments of the present invention can be achieved, and is specifically one kind selected from calcium oxide, magnesium oxide, strontium oxide, aluminum oxide and barium oxide, or a mixture or a solid-solution of two or more kinds of metal oxides selected from these. Specific examples of the mixture or solid-solution of two or more kinds of metal oxides selected from these include calcinated dromite (a mixture containing calcium oxide and magnesium oxide), calcinated hydrotalcite (a solid-solution of calcium oxide and aluminum oxide) and the like. Such hygroscopic metal oxides are known as hygroscopic materials in various technical fields, and commercially available products can be used. Specific examples include calcinated dromites (“KT” manufactured by Yoshizawa Lime Industry Co., Ltd., and the like), calcium oxides (“Moistop #10” manufactured by Sankyo Seifun and the like), magnesium oxides (“Kyowamag MF-150” and “Kyowamag MF-30” manufactured by Kyowa Chemical industry, “Puremag FNMG” manufactured by Tateho Chemical Industries Co., Ltd., and the like), light burned magnesium oxides (“#500”, “#1000” and “#5000” manufactured by Tateho Chemical Industries Co., Ltd., and the like), and the like.

The average particle size of the hygroscopic metal oxide is not specifically limited, and is preferably 10 μm or less, more preferably 5 μm or less, and further preferably 1 μm or less.

Furthermore, as the hygroscopic metal oxide, a hygroscopic metal oxide that has undergone a surface treatment with a surface treatment agent such as a higher aliphatic acid such as stearic acid, a known alkylsilane or a silane coupling agent can be used. By conducting such surface treatment, the reaction of the moisture in the resin with the hygroscopic metal oxide can be blocked.

The content of the hygroscopic metal oxide in the resin layer is preferably in the range of from 1 to 40% by mass with respect to 100% by mass of the non-volatile component in the resin composition.

[Inorganic Filler]

The resin composition that constitutes the resin layer can further contain a filler material having a flat plate-shaped particular form such as talc, clay, mica or boemite, and the resistance to moisture permeation of the resin layer can further be increased.

Furthermore, rubber particles can be incorporated, and the mechanical strength of the resin layer can be improved and the stress can be relaxed by incorporating the rubber particles. Core-shell type rubber particles may be used as the rubber particles, and specific examples include Staphyloid AC3832 and AC3816N (these are manufactured by Ganz Chemical Co., Ltd.), Metablen KW-4426 (manufactured by Mitsubishi Rayon Co., Ltd.), F351 (manufactured by Zeon Corporation) and the like. Specific examples of acrylonitrile-butadiene rubber (NBR) particles include XER-91 (manufactured by JSR) and the like. Specific examples of styrene-butadiene rubber (SBR) particles include XSK-500 (manufactured by JSR) and the like. Specific examples of acrylic rubber particles can include Metablen W300A and W450A (these are manufactured by Mitsubishi Rayon Co., Ltd.).

[Curing Accelerator]

In the resin composition that constitutes the resin layer in one or more embodiments of the present invention, a curing accelerator may further be incorporated so as to adjust the curing temperature, curing time and the like. Examples of the curing accelerator include quaternary ammonium salts such as tetramethylammonium bromide and tetrabutylammonium bromide, quaternary sulfonium salts such as tetraphenylphosphonium bromide and tetrabutylphosphonium bromide, diazabicyclo compounds such as DBU (1,8-diazabicyclo(5.4.0)undecene-7), DBN (1,5-diazabicyclo(4.3.0)nonene-5), DBU-phenol salt, DBU-octylacid salt, DBU-p-toluenesulfonic acid salt, DBU-formic acid salt and DBU-phenol-novolak resin salt, imidazole compounds such as 1-benzyl-2-methylimidazole, 1-benzyl-2-phenylimidazole and 2-ethyl-4-methylimidazole, tertiary amines such as tris(dimethylaminomethyl)phenol and benzyldimethylamine, dimethylurea compounds such as aromatic dimethylureas, aliphatic dimethylureas and aromatic dimethylureas, and the like.

The content in the case when the curing accelerator is used is in the range of 0.01 to 7% by mass with respect to the total amount of the thermal curable resin.

[Method for Forming Resin Layer]

The resin layer in one or more embodiments of the present invention may be formed by preparing a varnish in which a composition that constitutes the resin layer is dissolved, applying the composition onto a gas barrier layer mentioned below and drying the composition.

Specific examples of the organic solvent used for the preparation of the varnish include ketones such as acetone, methyl ethyl ketone (hereinafter also abbreviated as “MEK”) and cyclohexanone, acetate esters such as ethyl acetate, butyl acetate, cellosolve acetate, propylene glycol monomethyl ether acetate and carbitol acetate, carbitols such as cellosolve and butylcarbitol, aromatic hydrocarbons such as toluene and xylene, dimethylformamide, dimethylacetamide, N-methylpyrrolidone, and the like. These may be used by one kind, or in combination of two or more kinds.

As the application method, an optional and suitable method can be adopted. Specific examples include a roll coating process, a flow coating process, an inkjet process, a spray coating process, a printing process, a dip coating process, a casting film formation process, a bar coating process, a gravure printing process and the like.

The drying conditions are not specifically limited, and are preferably at from 50 to 100° C. for 3 to 15 minutes.

The thickness of the resin layer in one or more embodiments of the present invention is not specifically limited, and is preferably in the range of from 3 to 200 μm, more preferably in the range of from 5 to 150 μm, and further preferably in the range of from 10 to 100 μm, from the viewpoint that moisture is blocked by decreasing the contact surface area with outer air.

<<Gas Barrier Layer>>

The gas barrier layer in one or more embodiments of the present invention is a layer that is formed by subjecting a layer formed by applying an application liquid containing at least a polysilazane and drying the application liquid to a modification treatment, and in the case when plural gas barrier layers are present, the gas barrier layer is the layer that is present on the outermost surface and adjacent to the above-mentioned resin layer in one or more embodiments of the present invention. The adjacent layer means not only an embodiment in which the gas barrier layer is directly in contact with the resin layer, but also that other thin film layer may intervene within the scope in which the effect of the ionic liquid in one or more embodiments of the present invention is expressed.

[Polysilazane]

The polysilazane is a polymer having silicon-nitrogen bonds, and is a ceramic precursor inorganic polymer of SiO₂ and Si₃N₄, which have bonds such as Si—N, Si—H and N—H, and an intermediate solid-solution of both, SiOₓN_{y}, and the like.

Specifically, the polysilazane preferably has a structure of the following general formula (I)

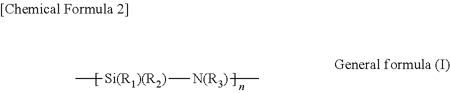

In the above-mentioned general formula (I), R₁, R₂ and R₃ are each independently a hydrogen atom, or a substituted or unsubstituted alkyl group, aryl group, vinyl group or (trialkoxysilyl)alkyl group. At this time, R₁, R₂ and R₃ may be the same or different from one another. Examples of the alkyl group include straight chain, branched chain or cyclic alkyl groups having a carbon atom number of from 1 to 8. More specific examples include a methyl group, an ethyl group, an n-propyl group, an isopropyl group, an n-butyl group, an isobutyl group, a sec-butyl group, a tert-butyl group, an n-pentyl group, an isopentyl group, a neopentyl group, an n-hexyl group, an n-heptyl group, an n-octyl group, a 2-ethylhexyl group, a cyclopropyl group, a cyclopentyl group, a cyclohexyl group and the like. Furthermore, examples of the aryl group include aryl groups having a carbon atom number of from 6 to 30. More specific examples include non-condensed hydrocarbon groups such as a phenyl group, a biphenyl group, a terphenyl group and the like; and condensed polycyclic hydrocarbon groups such as a pentalenyl group, an indenyl group, a naphthyl group, an azulenyl group, a heptalenyl group, a biphenylenyl group, a fluorenyl group, an acenaphthylenenyl group, a preadenyl group, an acenaphthenyl group, a phenalenyl group, a phenanthryl group, an anthryl group, a fluoranetenyl group, an acephenanethrylenyl group, an aceantrilenyl group, a triphenylenyl group, a pyrenyl group, a crycenyl group, a naphthacenyl group and the like. Examples of the (trialkoxysilyl)alkyl group include alkyl groups having a carbon atom number of from 1 to 8 and having a silyl group substituted with an alkoxy group having a carbon atom number of from 1 to 8. More specific examples include a 3-(triethoxysilyl)propyl group, a 3-(trimethoxysilyl)propyl group and the like. The substituents that are optionally present in the above-mentioned R₁ to R₃ are not specifically limited, and examples include alkyl groups, halogen atoms, a hydroxy group (—OH), a mercapto group (—SH), a cyano group (—CN), a sulfo group (—SO₃H), a carboxy group (—COOH), a nitro group (—NO₂) and the like. The substituents that are optionally present are not the same as R₁ to R₃ that are substituted. For example, in the case when R₁ to R₃ are alkyl groups, R₁ to R₃ are not further substituted with an alkyl group. Among these, R₁, R₂ and R₃ are preferably a hydrogen atom, a methyl group, an ethyl group, a propyl group, an isopropyl group, a butyl group, an isobutyl group, a tert-butyl group, a phenyl group, a vinyl group, a 3-(triethoxysilyl)propyl group or a 3-(trimethoxysilylpropyl) group.

Furthermore, in the above-mentioned general formula (I), n is an integer, and is preferably determined so that the polysilazane having the structure represented by the general formula (I) has a number average molecular weight of from 150 to 150,000 g/mol.

In the compound having a structure represented by the above-mentioned general formula (I), one or more embodiments contain a perhydropolysilazane wherein all of R₁, R₂ and R₃ are hydrogen atoms.

The polysilazane is commercially available in a solution state dissolved in an organic solvent, and a commercially available produced can be directly used as an application liquid for forming a gas barrier layer. Examples of the commercially available products of the polysilazane include Aquamica (registered trademark) NN120-10, NN120-20, NAX120-20, NN110, NN310, NN320, NL110A, NL120A, NL120-20, NL150A, NP110, NP140 and SP140 manufactured by AZ Electronic Materials, and the like.

Other examples of the polysilazane that can be used in one or more embodiments of the present invention may be, but is not limited to, polysilazanes that turns into ceramics at a low temperature such as a silicon alkoxide-added polysilazane obtained by reacting the above-mentioned polysilazane with a silicon alkoxide (JP 5-238827 A), a glycidol-added polysilazane obtained by reacting glycidol (JP 6-122852 A), an alcohol-added polysilazane obtained by reacting an alcohol (JP 6-240208 A), a metal carboxylic acid salt-added polysilazane obtained by reacting a metalcarboxylic acid salt (JP 6-299118 A), an acetylacetonate complex-added polysilazane obtained by reacting an acetylacetonate complex containing a metal (JP 6-306329 A) and a metal microparticle-added polysilazane obtained by adding metal microparticles (JP 7-196986 A).

In the case when the polysilazane is used, the content ratio of the polysilazane in the gas barrier layer before the modification treatment may be 100% by mass when the total mass of the gas barrier layer is deemed as 100% by mass. Furthermore, in the case when the gas barrier layer contains substances other than the polysilazane, the content ratio of the polysilazane in the layer is preferably in the range of from 10 to 99% by mass, more preferably in the range of from 40 to 95% by mass, and specifically preferably in the range of from 70 to 95% by mass.

[Application Liquid for Forming Gas Barrier Layer]

The solvent for preparing the application liquid for forming a gas barrier layer is not specifically limited as long as it can dissolve silicon compounds, and organic solvents that are free from water and reactive groups (for example, a hydroxyl group, or an amine group or the like), which easily react with silicon compound, and are inert against silicon compounds, are preferable, and aprotic organic solvents are more preferable. Specific examples of the solvents include aprotic solvents; for example, hydrocarbon solvents such as aliphatic hydrocarbons, alicyclic hydrocarbons and aromatic hydrocarbons such as pentane, hexane, cyclohexane, toluene, xylene, solvesso and terbene; halogen hydrocarbon solvents such as methylene chloride and trichloroethane; esters such as ethyl acetate and butyl acetate; ketones such as acetone and methyl ethyl ketone; ethers aliphatic ethers and alicyclic ethers such as dibutyl ether, dioxane and tetrahydrofuran: for example, tetrahydrofuran, dibutyl ether, mono- and polyalkylene glycol dialkyl ethers (diglymes) and the like can be exemplified.

The above-mentioned solvent is selected according to purposes such as the solubility of the silicon compound and the vaporization velocity of the solvent, and may be used singly or in the form of a mixture of two or more kinds.

The concentration of the silicon compound in the application liquid for forming a gas barrier layer is not specifically limited, and differ depending on the film thickness of the layer and the pot life of the application liquid, and is preferably from 1 to 80% by mass, more preferably from 5 to 50% by mass, and specifically preferably from 10 to 40% by mass.

Furthermore, the application liquid for forming a gas barrier layer may contain an aluminum compound from the viewpoint of the improvement of the heat-resistance of the gas barrier layer, and examples of the aluminum compound include aluminum trimethoxide, aluminum triethoxide, aluminum tri-n-propoxide, aluminum tri-isopropoxide, aluminum tri-n-butoxide, aluminum tri-sec-butoxide, aluminum tri-tert-butoxide, aluminum acetylacetonate, acetalkoxyaluminum diisopropylate, aluminum ethylacetacetate-di-isopropylate, aluminum ethylacetacetate-di-n-butylate, aluminum diethylacetacetate mono-n-butylate, aluminum diisopropylate mono-sec-butylate, aluminum trisacetyl acetonate, aluminum trisethyl acetacetate, bis(ethyl acetacetate) (2,4-pentanedionato)aluminum, aluminum alkylacetacetate diisopropylates, aluminum oxide isopropoxide trimer, aluminum oxideoctylate trimer and the like.

Specific examples of commercially available products include AMD (aluminum diisopropylate mono-sec-butylate), ASBD (aluminum secondary butylate), ALCH (aluminum ethylacetacetate-diisopropylate), ALCH-TR (aluminum trisethylacetacetate), Alumichlate M (aluminum alkyl acetacetate-diisopropylate), Alumichlate D (aluminum bisethylacetacetate-monoacetyl acetonate), Alumichlate A (W) (aluminum trisacetyl acetonate) (these are manufactured by Kawaken Fine Chemicals Co., Ltd.), Plenact (registered trademark) AL-M (acetalkoxy aluminum diisopropylate, manufactured by Ajinomoto Fine Chemicals), Orgatics series (manufactured by Matsumoto Fine Chemical Co., Ltd.) and the like. The content in the application liquid for a gas barrier layer formation is preferably from 0.1 to 10% by mass, and more preferably from 1 to 5% by mass.

[Method for Applying Gas Barrier Layer]

The formation method by the method for applying a gas barrier layer as mentioned above is not specifically limited, and a known method can be applied. Specific examples include a spin coating process, a roll coating process, a flow coating process, an inkjet process, a spray coating process, a printing process, a dip coating process, a cast film formation process, a bar coating process, a gravure printing process and the like.

A method including applying the application liquid for forming a gas barrier layer, which contains a silicon compound, and a catalyst as necessary in an organic solvent by the above-mentioned known application method, removing this solvent by vapolization, and then conducting a modification treatment is preferable.

The application thickness can be suitably preset depending on the purpose. For example, the application thickness per one gas barrier layer is such that the thickness after drying is preferably from about 10 nm to 10 μm, more preferably from 15 nm to 1 μm, further preferably from 20 to 500 nm. If the film thickness is 10 nm or more, a sufficient barrier property can be obtained, whereas when the film thickness is 10 μm or less, a stable application property can be obtained during layer formation, and a high light transmissivity can be realized.

After the application of the application liquid, the coating may be dried. By drying the coating, the organic solvent contained in the coating can be removed. At this time, all of the organic solvent contained in the coating may be dried, or a part of the organic solvent may remain. A gas barrier layer can be obtained even in the case when a part of the organic solvent is allowed to remain. The remaining solvent may be removed later.

<Treatment for Modifying Gas Barrier Layer>

The treatment for modifying a polysilazane in one or more embodiments of the present invention refers to a reaction for converting at least a part of the polysilazane to silicon oxide or silicon oxide nitride.

(Vacuum Ultraviolet Ray-Irradiation Treatment)

In the vacuum UV irradiation treatment in one or more embodiments of the present invention, the illuminance of the vacuum ultraviolet ray received by the polysilazane layer coating is preferably in the range of from 30 to 200 mW/cm², more preferably in the range of from 50 to 160 mW/cm². At 30 mW/cm² or more, there is no concern about decrease in modification efficiency, whereas 200 mW/cm² or less is preferable since abrasion is not provided to the coating and the substrate is not damaged.

The amount of the irradiated energy of the vacuum ultraviolet ray on the coating surface of the polysilazane layer is preferably in the range of from 200 to 10,000 mJ/cm², more preferably in the range of from 500 to 5,000 mJ/cm². In this range, cracks are not generated, and the substrate is not deformed by heat.

As the vacuum ultraviolet ray source, a rare gas excimer lamp is preferably used. Since the atoms of rare gases such as Xe, Kr, Ar, Ne and the like do not chemically bind to form molecules, the gases are called as inert gases.

An Xe excimer lamp emits ultraviolet ray having a short wavelength of 172 nm at a single wavelength, and thus is excellent in luminescence efficiency. This light has an absorption coefficiency of oxygen, and thus can generate radical oxygen atom species and ozone at high concentrations.

Furthermore, it is known that the energy of light having a short wavelength of 172 nm has a high ability to allow dissociation of the bonding of organic products. By this high energy that is possessed by active oxygen, ozone and ultraviolet ray irradiation can realize modification of the polysilazane layer within a short time.

The reaction during the irradiation of ultraviolet ray requires oxygen, but vacuum ultraviolet has absorption by oxygen and thus the efficiency in the ultraviolet irradiation step easily decreases. Therefore, the irradiation of vacuum ultraviolet ray may be conducted under a state at an oxygen concentration that is as low as possible. Namely, the oxygen concentration during the vacuum UV irradiation is preferably in the range of from 10 to 10,000 ppm, more preferably in the range of from 50 to 5,000 ppm, and further preferably in the range of from 1,000 to 4,500 ppm.

The gas that satisfies an irradiation atmosphere, which is used during the vacuum UV irradiation, is preferably a dried inert gas, and specifically preferably dried nitrogen gas in view of cost. The adjustment of the oxygen concentration can be adjusted by measuring the flow amounts of the oxygen gas and inert gas to be introduced into an irradiation chamber, and changing the ratio of the flow amounts.

[Other Gas Barrier Layer]

The gas barrier layer in one or more embodiments of the present invention may have a stacked structure of 2 or more layers as long as a layer that is formed by subjecting a layer that has been formed by applying and drying an application liquid containing a polysilazane to a modification treatment is present on the outermost layer. Plural gas barrier layers having the same composition may be formed, or plural layers having different compositions may be formed.

Furthermore, in the case of a stacked structure of two or more layers, the stacked structure may be a combination with a gas barrier layer formed by a chemical vapor deposition process (Chemical Vapor Deposition) such as a vacuum plasma CVD process or a physical vapor deposition process (Physical Vapor Deposition, PVD process) such as a sputtering process instead of the layer containing the polysilazane by conducting a modification treatment in one or more embodiments of the present invention.

From the viewpoint of achieving the flexibility, mechanical strength, durability during transportation by roll to roll and barrier performance of the sealing film of one or more embodiments of the present invention at the same time, a method including disposing a substrate on a pair of film formation rollers, and further forming a gas barrier layer on the substrate by a plasma CVD process including causing plasma by discharging between the above-mentioned pair of film formation rollers will be mentioned below as an example. In the explanation, the sealing film of one or more embodiments of the present invention is also referred to as a gas barrier film.

As an exemplary embodiment of the other gas barrier layer formed by the CVD process used in one or more embodiments of the present invention, the gas barrier layer may contain carbon, silicon and oxygen as the constitutional elements. Another embodiment may be a layer that satisfies the requirements of the following (i) to (iii).

(i) In a silicon distribution curve that shows the relationship between the distance (L) from the surface of the above-mentioned gas barrier layer in the film thickness direction of the gas barrier layer and the ratio of the amount of the silicon atom with respect to the total amount of the silicon atom, oxygen atom and carbon atom (silicon atom ratio), an oxygen distribution curve that shows the relationship between the above-mentioned L and the ratio of the amount of the oxygen atom with respect to the total amount of the silicon atom, oxygen atom and carbon atom (oxygen atom ratio), and a carbon distribution curve that shows the relationship between the above-mentioned L and the ratio of the amount of the carbon atom with respect to the total amount of the silicon atom, oxygen atom and carbon atom (carbon atom ratio), the atom ratio is much in the order of (oxygen atom ratio), (silicon atom ratio) and (carbon atom ratio) in the region of 90% or more (upper limit: 100%) of the film thickness of the above-mentioned gas barrier layer (the atomic ratios are O>Si>C);

(ii) the above-mentioned carbon distribution curve has at least two extremal values;

(iii) the absolute value of the difference between the maximum value and minimum value of the carbon atom ratio in the above-mentioned carbon distribution curve (hereinafter also simply referred to as “Cₘₐₓ−Cₘᵢₙ difference”) is 3 at % or more.

The above-mentioned silicon distribution curve, the above-mentioned oxygen distribution curve, the above-mentioned carbon distribution curve, and the above-mentioned oxygen carbon distribution curve can be prepared by a so-called XPS depth profile measurement, in which surface composition analyses are sequentially conducted while exposing the inner part of the sample by using a measurement of an X-ray photoelectron spectroscopy (XPS: X-ray Photoelectron Spectroscopy) and ion sputtering of a rare gas such as argon in combination. The distribution curves obtained by such XPS depth profile measurement can be prepared by, for example, by plotting the atom ratios of the respective elements (unit: at %) on the longitudinal axis and plotting the etching times (sputtering times) on the horizontal axis. In the distribution curves of the elements in which the etching times are plotted on the horizontal axis, since the etching times approximately correlate to the distance (L) from the surface of the above-mentioned gas barrier layer in the film thickness direction of the above-mentioned gas barrier layer in the film thickness direction, the distance from the surface of the gas barrier layer which is calculated from the relationship between the etching velocity and the etching time adopted during the measurement of the XPS depth profile can be adopted as “distance from the surface of the gas barrier layer in the film thickness direction of the gas barrier layer”. The silicon distribution curve, oxygen distribution curve, carbon distribution curve and oxygen carbon distribution curve can be prepared under the following measurement conditions.

(Measurement Conditions)

Etching ion species: argon (Ar⁺)

Etching velocity (a value in SiO₂ thermal oxidized film equivalent): 0.05 nm /sec

Etching interval (a value in SiO₂ equivalent): 10 nm

X-ray photoelectron spectrometer: manufactured by Thermo Fisher Scientific, model name “VG Theta Probe”

Irradiated X-ray: single crystalline spectrum AlKα

Spot and size of X-ray: oval shape of 800×400 μm.

The above-mentioned gas barrier layer may be such that (ii) the above-mentioned carbon distribution curve has at least two extremal values. The gas barrier layer is more preferably such that the above-mentioned carbon distribution curve has at least three extremal values, further preferably such that the carbon distribution curve has at least four extremal values, and the carbon distribution curve may have five or more extremal values. In the case when the above-mentioned carbon distribution curve has one or less extremal value, the gas barrier property in the case when the obtained gas barrier film is bent may become insufficient. The upper limit of the extremal value of the carbon distribution curve is not specifically limited, and for example, is preferably 30 or less, more preferably 25 or less, but the number of the extremal values is also attributable to the film thickness of the gas barrier layer, and thus cannot be completely defined.

In the case when the above-mentioned carbon distribution curve has at least three extremal values, the absolute values of the difference between the distances (L) from the surface of the above-mentioned gas barrier layer in the film thickness direction of the above-mentioned gas barrier layer on one extremal value possessed by the above-mentioned carbon distribution curve and the extremal value that is adjacent to the above-mentioned extremal value (hereinafter simply referred to as “distances between extremal values”) are either preferably 200 nm or less, more preferably 100 nm or less, specifically preferably 75 nm or less. In such distances between the extremal values, sites each having a large carbon atom ratio (maximal values) are present at a suitable frequency in the gas barrier layer, and thus suitable flexibility can be provided to the gas barrier layer, and generation of cracks during the bending of the gas barrier film can be suppressed and prevented more effectively. In this specification, “extremal value” refers to a maximal value or minimal value of the atom ratio of the element to the distance (L) from the surface of the above-mentioned gas barrier layer in the film thickness direction of the above-mentioned first gas barrier layer. Furthermore, in this specification, “maximal value” refers to a point where the value of the atom ratio of the element (oxygen, silicon or carbon) changes from increase to decrease in the case when the distance from the surface of the gas barrier layer is changed, and the value of the atom ratio of the element on the position where the distance from the surface of the gas barrier layer in the film thickness direction of the gas barrier layer is further changed in the range of from 4 to 20 nm from the value of the atom ratio of the element of the above-mentioned point decreases by 3 at % or more. Specifically, it is sufficient that the value of the atom ratio of the element decreases by 3 at % or more in either range when the distance is changed in the range of from 4 to 20 nm. Similarly, in this specification, “minimal value” refers to a point where the value of the atom ratio of the element (oxygen, silicon or carbon) changes from decrease to increase in the case when the distance from the surface of the gas barrier layer is changed, and the value of the atom ratio of the element on the position where the distance from the surface of the gas barrier layer in the film thickness direction of the gas barrier layer is further changed in the range of from 4 to 20 nm from the value of the atom ratio of the element of the above-mentioned point increases by 3 at % or more. Specifically, it is sufficient that the value of the atom ratio of the element increases by 3 at % or more in either range when the distance is changed in the range of from 4 to 20 nm. The lower limit of the distance between the extremal values in the case of having at least three extremal values is not specifically limited, since the lower the distance between the extremal value is, the higher the effect of improving suppression/prevention of cracks during the bending of the gas barrier property film is. However, the distance is preferably 10 nm or more, more preferably 30 nm or more, with consideration for the flexibility, effect of suppressing/preventing cracks, heat expansion property and the like of the gas barrier layer.

Furthermore, the gas barrier layer may be such that (iii) the absolute value of the difference between the maximum value and minimum value of the carbon atom ratio in the above-mentioned carbon distribution curve (hereinafter simply referred to as “Cₘₐₓ−Cₘᵢₙ difference”) is 3 at % or more. When the above-mentioned absolute value is lower than 3 at %, the gas barrier property may become insufficient in the case when the obtained gas barrier film is bent. The Cₘₐₓ−Cₘᵢₙ difference is preferably 5 at % or more, more preferably 7 at % or more, specifically preferably 10 at % or more. By providing the above-mentioned Cₘₐₓ−Cₘᵢₙ difference, the gas barrier property can further be improved. “Maximum value” in this specification refers to the atom ratios of the respective elements which are maximal in the distribution curves of the respective elements, and is the highest value among the local maximum values. Similarly, in this specification, “minimum value” refers to the atom ratios of the respective element which are minimal in the distribution curves of the respective elements, and is the lowest value among the local minimum values. The upper limit of the Cₘₐₓ−Cₘᵢₙ difference is not specifically limited, and is preferably 50 at % or less, more preferably 40 at % or less with consideration for the effect of improving suppression/prevention of generation of cracks during the bending of the gas barrier film.

The film thickness (dry film thickness) of the gas barrier layer formed by the above-mentioned plasma CVD process is not specifically limited as long as the above-mentioned (i) to (iii) are satisfied. For example, the film thickness per one layer of the gas barrier layer is preferably from 20 to 3,000 nm, more preferably from 50 to 2,500 nm, specifically preferably from 100 to 1,000 nm. At such film thickness, the gas barrier film can exert an excellent gas barrier property and an excellent effect of suppressing/preventing generation of cracks during bending. In the case when the barrier layer formed by the above-mentioned plasma CVD process is constituted by two or more layers, each gas barrier layer may have the film thickness as mentioned above.

In one or more embodiments of the present invention, from the viewpoint that a barrier layer having an even and excellent gas barrier property throughout the film surface is formed, the above-mentioned gas barrier layer may be substantially even in the film surface direction (the direction that is in parallel to the surface of the gas barrier layer). That the gas barrier layer is substantially even in the film surface direction refers to that, in the case when the above-mentioned oxygen distribution curve, the above-mentioned carbon distribution curve and the above-mentioned oxygen carbon distribution curve are prepared for the optional two measured portions of the film surface of the barrier layer by an XPS depth profile measurement, the numbers of the extremal values possessed by the carbon distribution curves obtained on the optional two measured portions are the same, and the absolute values of the difference of the maximum value and minimum value of the carbon atom ratio in the respective carbon distribution curves are identical with each other or differ within 5 at %.

The details of the relationship of the composition of the gas barrier layer and the gas barrier property and the carbon distribution curve, and the like are described in JP 2010-260347 A and JP 2011-73430 A and are well-known, and thus detailed explanations are omitted.

(Method for Formation of Other Gas Barrier Layer by Plasma CVD Process)

As the method for forming other gas barrier layer on the surface of the substrate, a plasma CVD process may be adopted in view of gas barrier property.

The method for forming a gas barrier layer by a plasma CVD process, which includes disposing a substrate on a pair of film formation rollers, and discharging between the pair of film formation rollers to generate plasma, will be explained below in detail with referring to FIG. 2. FIG. 2 is a schematic drawing that shows an example of a production device that can be preferably utilized for producing a gas barrier layer by this production method. Furthermore, in the following explanation and drawings, an identical symbol is provided to identical or corresponding factors, and overlapped explanations are omitted.

The production device 31 shown in FIG. 2 includes a sending roller 32, transport rollers 33, 34, 35 and 36, film formation rollers 39 and 40, a gas supply tube 41, a power source for generating plasma 42, electric field generators 43 and 44 that are installed in the film formation rollers 39 and 40, and a winding roller 45. Furthermore, in such production device, at least the film formation rollers 39 and 40, the gas supply tube 41, the power source for generating plasma 42, and the electric field generators 43 and 44 are disposed in a vacuum chamber, for which illustration is omitted. Furthermore, in such production device 31, the above-mentioned vacuum chamber is connected to a vacuum pump, for which illustration is omitted, and the pressure in the vacuum chamber can be suitably adjusted by such vacuum pump.

By using such production device 31 shown in FIG. 2, the gas barrier layer in one or more embodiments of the present invention can be produced by suitably adjusting, for example, the kind of the raw material gas, the electrical power of the electrode drum of the plasma generation device, the pressure in the vacuum chamber, the diameter of the film formation roller, and the transport velocity of the film (substrate).

As the film formation gas that is supplied from the above-mentioned gas supply tube 41 to an opposed space (a raw material gas or the like), a raw material gas, a reaction gas, a carrier gas and a discharging gas can be used singly or by mixing two or more kinds. The raw material gas in the above-mentioned film formation gas used for the formation of the gas barrier layer 1b can be suitably selected and used depending on the material of the gas barrier layer 1b to be formed. As such raw material gas, for example, an organic compound gas containing an organic silicon compound containing silicon and carbon can be used. Examples of such organic silicon compound include hexamethyldisiloxane (HMDSO), hexamethyldisilane (HMDS), 1,1,3,3-tetramethyldisiloxane, vinyltrimethylsilane, methyltrimethylsilane, hexamethyldisilane, methylsilane, dimethylsilane, trimethylsilane, diethylsilane, propylsilane, phenylsilane, vinyltriethoxysilane, vinyltrimethoxysilane, tetramethoxysilane (TMOS), tetraethoxysilane (TEOS), phenyltrimethoxysilane, methyltriethoxysilane and octamethylcyclotetrasiloxane. Among these organic silicon compound, hexamethyldisiloxane and 1,1,3,3-tetramethyldisiloxane are preferable in view of properties such as the handling property of the compound and the gas barrier property of the obtained first gas barrier layer. These organic silicon compounds can be used singly, or in combination of two or more kinds.

Furthermore, as the above-mentioned film formation gas, a reaction gas may also be used besides the above-mentioned raw material gas. As such reaction gas, a gas that is converted to an inorganic compound such as an oxide or a nitride by reacting with the above-mentioned raw material gas can be suitably selected and used. As the reaction gas for forming the oxide, for example, oxygen and ozone can be used.

As mentioned above, the barrier layer in one or more embodiments of the present invention may be subjected to film formation by a plasma CVD process using a plasma CVD device having counter roll electrodes (a roll-to-roll system) shown in FIG. 2. This is because, in the case of mass-produce using a plasma CVD device (roll-to-roll system) having counter roll electrodes, a gas barrier layer that is excellent in flexibility and achieves a mechanical strength, specifically durability during the transportation by roll-to-roll, and a barrier performance at the same time can be produced efficiently. Such production device is also excellent in that a gas barrier film for which durability against temperature change, which is used in solar batteries, electron parts and the like, is required can be mass-produced in an inexpensive and easy manner.

<<Substrate>>

In the sealing film of one or more embodiments of the present invention, a plastic film or a plastic sheet is preferably used as the substrate, and a film or sheet formed of a colorless and transparent resin is used more preferably. The material, thickness and the like of the plastic film used are not specifically limited as long as it is a film that can retain the gas barrier layer and the resin layer, and can be suitably selected depending on the purpose of use and the like. Specific examples of the above-mentioned plastic film include thermoplastic resins such as polyester resins, methacrylic resins, methacrylic acid-maleic acid copolymers, polystyrene resins, transparent fluorine resins, polyimides, fluorinated polyimide resins, polyamide resins, polyamide imide resins, polyetherimide resins, cellulose acylate resins, polyurethane resins, polyether ether ketone resins, polycarbonate resins, alicyclic polyolefin resins, polyarylate resins, polyether sulfone resins, polysulfone resins, cycloolefin copolymers, fluorine ring-modified polycarbonate resins, alicycle-modified polycarbonate resins, fluorine ring-modified polyester resins and acryloyl compounds.

Since the sealing film of one or more embodiments of the present invention is utilized as an electronic device such as an organic EL element, the substrate maybe transparent. Specifically, the substrate may have a light transmittance of generally 80% or more, preferably 85% or more, further preferably 90% or more. The light transmittance can be calculated by the method described in JISK105: 1981, i.e., by measuring a total light transmittance and a scattered light amount by using an integrating sphere light transmittance measurement device, and subtracting a diffusion transmittance from the total light transmittance.

The thickness of the substrate used for the sealing film of one or more embodiments of the present invention is suitably selected depending on use and thus is not specifically limited, and is typically from 1 to 800 μm, preferably from 10 to 200 μm. These plastic films may have functional layers such as a transparent conductive layer, a primer layer and a clear hard coat layer. With respect to the functional layer, besides the above-mentioned functional layers, the functional layers described in paragraphs “0036” to “0038” of JP 2006-289627 A can be preferably adopted.

The substrate is preferably a substrate with a surface having a high smoothness. The smoothness of the surface is preferably such that the average surface roughness (Ra) is 2 nm or less. There is no specific lower limit, but the average surface roughness is 0.01 nm or more in practical use. Where necessary, the smoothness may be improved in advance by polishing the both surfaces of the substrate, at least the side on which the gas barrier layer is to be disposed.

<<Sealing of Functional Element>>

The functional element to be sealed by using the sealing film of one or more embodiments of the present invention will be explained.

The functional element specifically refers to a flexible electronic device such as an organic EL element or a solar battery element. Sealing of an organic EL element will be explained with exemplification since the sealing film is preferably used specifically as a sealing film for an organic EL element.

[Constitution of Organic EL Element]

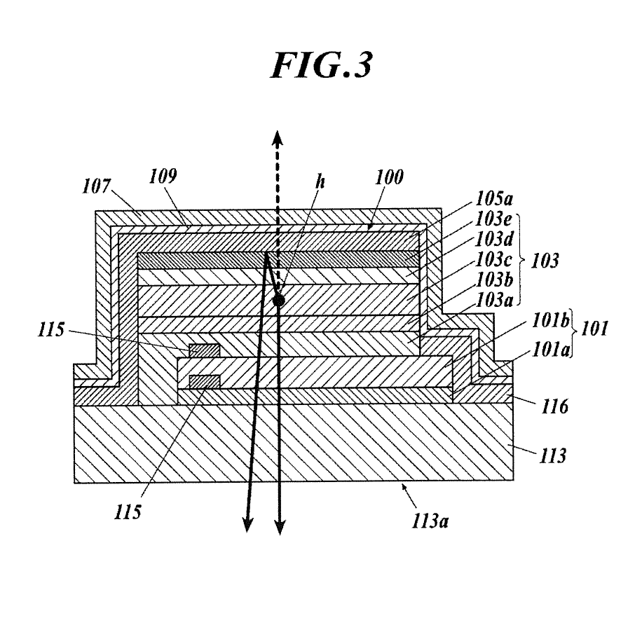

The organic EL element in one or more embodiments of the present invention may have various constitutions, and an example is shown in FIG. 3.

In FIG. 3, in the case when a resin substrate is used as the substrate used in the organic EL element will be explained.

The inorganic EL element 100 according to one or more embodiments of the present invention is disposed on the resin substrate 113, and is constituted by stacking a first electrode (transparent electrode) 101, an organic functional layer (luminescent functional layer) 103, which is constituted by using an organic material and the like, and a second electrode (counter electrode) 105a in this order from the side of the resin substrate 113. An extraction electrode 116 is disposed on the end part of the first electrode 101 (electrode layer 101b). The first electrode 101 and an external power source (illustration is omitted) are electrically connected through an extraction electrode 116. The organic EL element 100 is constituted so that generated light (emitted light h) is extracted from at least the side of the resin substrate 113.

Furthermore, the layer structure of the organic EL element 100 is not limited, and may be a general layer structure. Here, it is deemed that the first electrode 101 functions as an anode (i.e., an anode) and the second electrode 105a functions as a cathode (i.e., a cathode). In this case, for example, as the organic functional layer 103, a constitution in which a hole injection layer 103a/a hole transport layer 103b/a light-emitting layer 103c/an electron transport layer 103d/an electron injection layer 103e are stacked in this order from the side of the first electrode 101, which is an anode, is exemplified, and among these, it is essential to have at least the light-emitting layer 103c that is constituted by using an organic material. The hole injection layer 103a and the hole transport layer 103b may also be disposed as a hole transport-injection layer. The electron transport layer 103d and the electron injection layer 103e may also be disposed as an electron transport-injection layer. Furthermore, among these organic functional layers 103, for example, the electron injection layer 103e may be constituted by an inorganic material.

Furthermore, the organic functional layer 103 may be such that a hole blocking layer, an electron blocking layer and the like are stacked on necessary portions as necessary besides these layers. Furthermore, the light-emitting layer 103c may have a structure having light-emitting layers having respective colors that generates emitted lights at respective wavelength regions, wherein these light-emitting layers of respective colors are stacked through nonluminescent intermediate layers. The intermediate layers may function as hole blocking layers and electron blocking layers. Furthermore, the second electrode 105a, which is a cathode, may also have a stacked structure as necessary. In such constitution, only the part where the organic functional layer 103 is sandwiched between the first electrode 101 and the second electrode 105a becomes a luminescent region in the organic EL element 100.

Furthermore, in the layer constitution as mentioned above, an auxiliary electrode 115 may be disposed so as to be in contact with the electrode layer 101b of the first electrode 101 for the purpose of decreasing the resistance of the first electrode 101.

The organic EL element 100 having a constitution as mentioned above is sealed by the above-mentioned sealing film 107 on the resin substrate 113 for the purpose of preventing the deterioration of the organic functional layer 103, which is constituted by using an organic material and the like. This sealing film 107 is fixed on the side of the resin substrate 113 through the resin layer in one or more embodiments of the present invention, which functions as an adhesive. However, the terminal parts of the first electrode 101 (extraction electrode 116) and the second electrode 105a are disposed in the state that they are exposed from the sealing film 107 in the state that the insulation properties are retained from each other by the organic functional layer 103 on the resin substrate 113.

[Method for Producing Organic EL Element]

The method for producing an organic EL element used in one or more embodiments of the present invention includes a stacking step, in which a first electrode, an organic functional layer and a second electrode are formed by stacking on a resin substrate. With respect to the production method, a conventionally-known production method can be used.

### EXAMPLES

One or more embodiments of the present invention will be specifically explained below with referring to Examples, but the present invention is not limited to these. In the Examples, an indication of “part(s)” or “%” is used, and the indication represents “part(s) by mass” or “% by mass” unless otherwise specified.

Furthermore, in the following operations, the operation and measurements of the physical properties and the like were conducted under conditions of room temperature (20 to 25° C.)/relative humidity 40 to 50%, unless otherwise specified.

“Production of Sealing Film 1”

[Formation of Gas Barrier Layer A10]

(Preparation of Polysilazane-Containing Application Liquid)

A dibutyl ether solution containing 20% by mass of catalyst-free perhydropolysilazane (Aquamica (registered trademark) NN120-20 manufactured by AZ Electronic Materials) and a dibutyl ether solution containing 20% by mass of perhydropolysilazane containing 5% by mass of an amine catalyst (N,N,N′,N′-tetramethyl-1,6-diaminohexane (TMDAH)) (Aquamica (registered trademark) NAX120-20 manufactured by AZ Electronic Materials) were mixed at a ratio of 4:1, and an application liquid is prepared by diluting with a solvent in which dibutyl ether and 2,2,4-trimethylpentane had been mixed so that the mass ratio became 65:35, so that the solid content of the application liquid became 5% by mass.

The application liquid obtained above was subjected to film formation on a PET substrate provided with a clear hard coat (125 μm thickness) manufactured by Kimoto by using a spin coater so as to give a thickness of 300 nm, left for 2 minutes, and subjected to a thermal treatment on a hot plate at 80° C. for 1 minute, whereby a polysilazane coating was formed.

After the polysilazane coating was formed, polysilazane coating was subjected to a vacuum UV irradiation treatment at 6,000 mJ/cm² according to the following method, whereby a gas barrier layer A10 was formed.

<Conditions for Irradiation of Vacuum UV, and Measurement of Irradiation Energy>

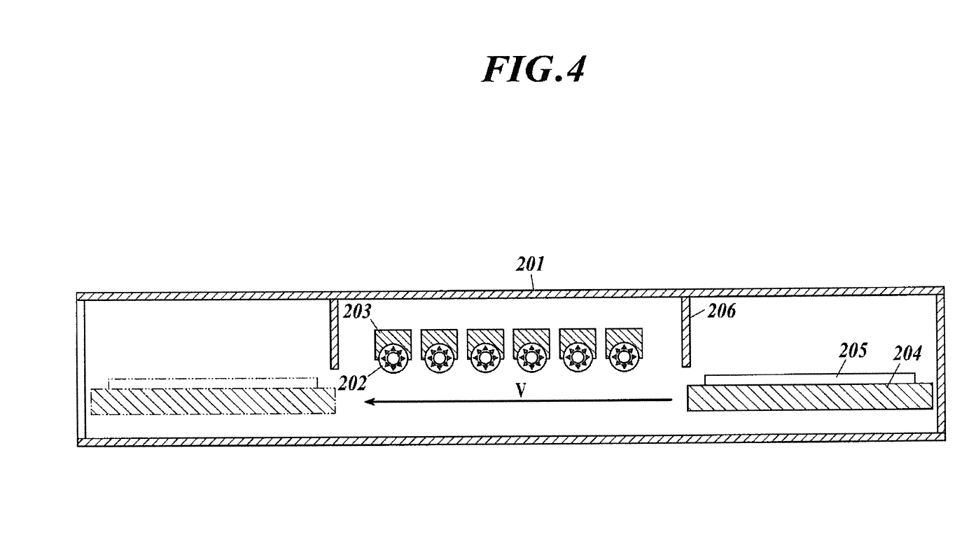

The vacuum UV irradiation was conducted by using the device as shown by a schematic drawing in FIG. 4.

In FIG. 4, reference numeral 201 denotes a device chamber, and the oxygen concentration can be maintained at a predetermined concentration by supplying suitable amounts of nitrogen and oxygen to the inside from gas supply inlets, which are not illustrated, and ejecting the gases from gas ejection outlets, which are not illustrated, to thereby substantially remove the water vapor from the inside of the chamber. Reference numeral 202 denotes an Xe excimer lamp having a double tube structure that irradiates vacuum ultraviolet ray at 172 nm, and reference numeral 203 denotes a holder for an excimer lamp which also serves as an external electrode. Reference numeral 204 denotes a sample stage. The sample stage 204 can transfer in a reciprocation manner at a predetermined velocity horizontally in the device chamber 201 by a transfer means, which is not illustrated. Furthermore, the sample stage 204 can be maintained at a predetermined temperature by a heating means, which is not illustrated. Reference numeral 205 denotes a sample on which a polysilazane coating has been formed. The height of the sample stage is adjusted so that the shortest distance between the surface of the application layer of the sample and the surface of the excimer lamp tube become 3 mm when the sample stage is horizontally transferred. Reference numeral 206 denotes a light blocking plate, and prevents the application layer of the sample from being irradiated with vacuum ultraviolet ray during the aging of the Xe excimer lamp 202.

The energy irradiated on the vacuum coating surface in the UV irradiation step was measured by using a ultraviolet integral light counter: C8026/H8025 UV POWER METER manufactured by Hamamatsu Photonics K.K., and using a sensor head of 172 nm. In the measurement, the sensor head was installed on the center of the sample stage 204 so that the shortest distance between the surface of the Xe excimer lamp tube and the measurement surface of the sensor head became 3 mm, and nitrogen and oxygen were supplied so that the atmosphere in the device chamber 201 had an identical oxygen concentration to that in the vacuum UV irradiation step, and the measurement was conducted by transferring the sample stage 204 at a velocity of 0.5 m/min (V in FIG. 4). Prior to the measurement, in order to stabilize the illuminance of the Xe excimer lamp 12, an aging time for 10 minutes was provided after the lighting of the Xe excimer lamp, and the measurement was then initiated by transferring the sample stage.

Based on the irradiation energy obtained by this measurement, the irradiation energy was adjusted to be 6,000 mJ/cm² by adjusting the transfer velocity of the sample stage. The vacuum UV irradiation was conducted after the aging for 10 minutes in a similar manner to that in the measurement of the irradiation energy.

[Formation of Resin Layer]

(Preparation of Ionic Liquid-Containing Application Liquid)

A mixture formed by mixing 30 parts by mass of a liquid bisphenol A-type epoxy resin (“828EL” manufactured by Japan Epoxy Resin), 20 parts by mass of orthotoluidine diglycidylamine (“GOT” manufactured by Nippon Kayaku Co., Ltd.), 8 parts by mass of an acrylic-based core-shell resin (“F351” manufactured by ZEON Corporation), 18 parts by mass of a solid dispersion-type curing agent (“VDH-J” manufactured by Ajinomoto Fine-Techno Co., Inc.), 2 parts by mass of a solid dispersion-type curing agent (“PN40-J” manufactured by Ajinomoto Fine-Techno Co., Inc.), 85 parts by mass of a solution of 70% by mass solid content of a biphenylaralkyl-type epoxy resin (“NC3000” manufactured by Nippon Kayaku Co., Ltd.) in methyl ethyl ketone (referred to as MEK), and 60 parts by mass of a 35% by mass MEK solution of a phenoxy resin (“YX6954” manufactured by Japan Epoxy Resin) by using a robomix type mixer stirrer Adi-Homo Mixer (manufactured by PRIMIX Corporation) was mixed with 3 parts by mass of an ionic liquid 1 (N-acetylglycine 1,1-dimethylpyrrolidinium salt), 15 parts by mass of a solvent (MEK) and 20 parts by mass of a solvent (acetone), and the mixture was homogeneously dispersed by a high-speed rotational mixer to give a varnish-like ionic liquid-containing application liquid. The ionic liquid-containing application liquid was homogeneously applied by an applicator on the barrier layer A10 obtained above so that the thickness of the thermal curable resin layer after the drying became 40 μm, and dried at from 60 to 80° C. for 6 minutes to give the sealing film 1 of one or more embodiments of the present invention.

“Production of Sealing Film 2”

The sealing film 2 of one or more embodiments of the present invention was obtained in a completely similar manner to that in “Production of sealing film 1”, except that the ionic liquid was changed to an ionic liquid 2 (N-acetylglycine tetrabutylphosphonium salt).

“Production of Sealing Film 3”

The sealing film 3 of one or more embodiments of the present invention was obtained in a completely similar manner to that in “Production of sealing film 1”, except that the ionic liquid was changed to an ionic liquid 3 (1-ethyl-3-methylimidazolium formate salt).

“Production of Sealing Film 4”

### [Formation of Gas Barrier Layer A11]

A gas barrier layer A11 was formed in a completely similar manner to that [Formation of gas barrier layer A10], except that the thickness of the gas barrier layer was changed to 150 nm.

[Formation of Gas Barrier Layer Gas Barrier Layer A21]

A dibutyl ether solution containing 20% by mass of perhydropolysilazane (Aquamica (registered trademark) NN120-20 manufactured by AZ Electronic Materials) was diluted to 5% by mass concentration with dibutyl ether, N,N,N′,N′-tetramethyl-1,6-diaminohexane (TMDAH) as an amine catalyst was then added thereto in an amount of 1% by mass with respect to the perhydropolysilazane, and ALCH (aluminum ethyl acetacetate-diisopropylate, manufactured by Kawaken Fine Chemicals Co., Ltd.) was further added thereto in an amount of 1% by mass with respect to the perhydropolysilazane, whereby an application liquid was prepared. Using the application liquid, a polysilazane coating having a thickness of 150 nm was formed on the gas barrier layer A11 obtained above, and the polysilazane coating was then subjected to a vacuum UV irradiation treatment at a dew point of −30° C. in an irradiation amount of 6,000 mJ/cm² by a method similar to that in the formation of the above-mentioned gas barrier layer A10 (application process), whereby a gas barrier layer A21 was formed.

The ionic liquid-containing application liquid obtained in the above-mentioned “Production of sealing film 1” was homogeneously applied by an applicator onto the above-mentioned gas barrier layer A21 so that the thickness of the thermal curable resin layer after the drying became 40 μm, and dried at 60 to 80° C. for 6 minutes to give the sealing film 4 of one or more embodiments of the present invention.

“Production of Sealing Film 5”

The sealing film 5 of one or more embodiments of the present invention was obtained in a completely similar manner to that in “Production of sealing film 4”, except that the ionic liquid was changed to the ionic liquid 2.

“Production of Sealing Film 6”

### [Formation of Gas Barrier Layer C11 (Sputtering Process)]

A transparent resin substrate with a hard coat layer (intermediate layer) (a polyethylene telephthalate (PET) film with a clear hard coat layer (CHC) manufactured by Kimoto) was set in a vacuum bath of a sputtering device manufactured by ULVAC, Inc., the vacuum bath was evacuated to the order of 10⁻⁴ Pa, and argon as a discharging gas was introduced at a partial pressure of 0.5 Pa. At the time when the atmospheric pressure had been stabilized, discharging was initiated to allow generation of plasma on a silicon oxide (SiOₓ) target, and a sputtering process was initiated. The shutter was opened at the time when the process had been stabilized, and formation of a silicon oxide film (SiOₓ) on the film was initiated. The film formation was completed by closing the shutter at the time when a film of 150 nm had been deposited, whereby a gas barrier layer C11 was formed.

[Formation of Gas Barrier Layer A11]

A gas barrier layer A11 was formed on the gas barrier layer C11 in a completely similar manner to that in [Formation of gas barrier layer A10], except that the thickness of the gas barrier layer was changed to 150 nm.

The ionic liquid-containing application liquid obtained in the above-mentioned “Production of sealing film 1” was homogeneously applied by an applicator onto the above-mentioned gas barrier layer A11 so that the thickness of the thermal curable resin layer after the drying became 40 μm, and dried at 60 to 80° C. for 6 minutes, whereby the sealing film of one or more embodiments of the present invention 6 was obtained.

“Production of Sealing Film 7”

[Formation of Gas Barrier Layer C21 (Plasma CVD1 Process)]

A PET substrate (125 μm thickness) provided with a clear hard coat manufactured by Kimoto was set in a production device 31 as shown in FIG. 2, and transported. Plasma was generated by applying a magnetic field between the film formation roller 39 and the film formation roller 40, and respectively applying an electrical power to the film formation roller 39 and the film formation roller 40 to discharge plasma between the film formation roller 39 and the film formation roller 40. Subsequently, a mixed gas of a film formation gas (hexamethyldisiloxane (HMDSO) as a film formation gas and an oxygen gas as a reaction gas (this also functions as a discharging gas) was supplied to the formed discharging region, and a gas barrier layer C21 having a thickness of 150 nm was formed by a plasma CVD process on the substrate. This film formation method is referred to as a CVD1 process.

The conditions for the film formation were as follows.

(Conditions for Film Formation)

Supply amount of raw material gas: 50 sccm (Standard Cubic Centimeter per Minute, 0° C., on the basis of 1 atmospheric pressure)

Supply amount of oxygen gas: 500 sccm (0° C., on the basis of 1 atmospheric pressure)

Vacuum degree in vacuum chamber: 3 Pa

Electrical power applied by power source for generating plasma: 0.8 kW

Frequency wave number of power source for generating plasma: 70 kHz

Transport velocity of Film: 1.0 m/min

It was confirmed that the gas barrier layer C21 satisfied the following (i) to (iii) when a carbon distribution curve, a silicon distribution curve and an oxygen distribution curve were prepared by the above-mentioned XPS depth profile measurement.

(i) The atom ratios were in the order of (oxygen atom ratio)>(silicon atom ratio)>(carbon atom ratio) in the region of 90% or more of the distance (L) from the above-mentioned gas barrier layer surface in the film thickness direction of the gas barrier layer.

(ii) The above-mentioned carbon distribution curve has at least two extremal values.

(iii) The absolute value of the difference of the maximum value and minimum value of the carbon atom ratio in the above-mentioned carbon distribution curve is 3 at % or more.

[Formation of Gas Barrier Layer A11]

A gas barrier layer A11 was formed on the gas barrier layer C21 obtained above.

The ionic liquid-containing application liquid obtained in the above-mentioned “Production of sealing film 1” was homogeneously applied by an applicator on the above-mentioned gas barrier layer A11 so that the thickness of the thermal curable resin layer after the drying became 40 μm, and dried at 60 to 80° C. for 6 minutes, whereby the sealing film of one or more embodiments of the present invention 7 was obtained.

“Production of Sealing Film 8”

The sealing film 8 of one or more embodiments of the present invention was obtained in a completely similar manner to that in “Production of sealing film 7”, except that the gas barrier layer A11 was changed to a gas barrier layer A21.

“Production of Sealing Film 9”

[Formation of Gas Barrier Layer C12 (Sputtering Process)]

A gas barrier layer C12 was formed in a completely similar manner to that in [Formation of gas barrier layer C11] in that the thickness of the gas barrier layer to 100 nm.

[Formation of Gas Barrier Layer A12]

A gas barrier layer A12 was formed on the gas barrier layer C12 in a completely similar manner to that in [Formation of gas barrier layer A11], except that the thickness of the gas barrier layer was changed to 100 nm.

[Formation of Gas Barrier Layer A22]

A gas barrier layer A22 was formed on the gas barrier layer A12 in a completely similar manner to that in [Formation of gas barrier layer A21], except that the thickness of the gas barrier layer was changed to 100 nm.

The ionic liquid-containing application liquid obtained in the above-mentioned “Production of sealing film 1” was homogeneously applied by an applicator on the above-mentioned gas barrier layer A22 so that the thickness of the thermal curable resin layer after the drying became 40 μm, and dried at 60 to 80° C. for 6 minutes, whereby the sealing film of one or more embodiments of the present invention 9 was obtained.

“Production of Sealing Film 10”

[Formation of Gas Barrier Layer C22 (Plasma CVD Process)]

A gas barrier layer C22 was formed in a completely similar manner to that in [Formation of gas barrier layer C21] in that the thickness of the gas barrier layer to 100 nm.

The sealing film 10 of one or more embodiments of the present invention was obtained in a completely similar manner to that in “Production of sealing film 9”, except that the gas barrier layer C21 was changed to the above-mentioned gas barrier layer C22.

“Production of Sealing Film Sealing Film 11”

[Formation of Gas Barrier Layer C23 (Plasma CVD2 Process)]

A gas barrier layer C23 having a thickness of 100 nm was formed by a plasma discharge system according to the conditions described below, while a PET substrate provided with a clear hard coat (125 μm thickness) manufactured by Kimoto was transported. This film formation method is referred to as a CVD2 process.

(Formation of Gas Barrier Layer C23)

<Composition of Mixed Gas for Formation of Gas Barrier Layer C23>

Discharging gas: nitrogen gas 94.9% by volume

Thin film formation gas: tetraethoxysilane 0.5% by volume

Addition gas: oxygen gas 5.0% by volume

(Conditions for Film Formation of Gas Barrier Layer)

First electrode side Kind of power source: manufactured by Oyo Electric Co., Ltd., 80 kHz

Frequency wave number: 80 kHz

Output density: 8 W/cm²

Electrode temperature: 120° C.

Second electrode side Kind of power source: manufactured by Pearl Industrial Ltd., 13.56 MHz CF-5000-13M

Frequency wave number: 13.56 MHz

Output density: 10 W/cm²

Electrode temperature: 90° C.

When a carbon distribution curve, a silicon distribution curve and an oxygen distribution curve were prepared by an XPS depth profile measurement, it was confirmed that the gas barrier layer C23 was such that the distributions were each constant in the film thickness direction, and thus did not satisfy the above-mentioned (i) to (iii).

Subsequently, the sealing film 11 of one or more embodiments of the present invention was obtained in a completely similar manner to that in “Production of sealing film 10”, except that the gas barrier layer C22 was changed to the above-mentioned gas barrier layer C23.

“Production of Sealing Film 12”

[Formation of Gas Barrier Layer C10]

A gas barrier layer C10 was formed in a completely similar manner to that [Formation of gas barrier layer C11], except that the thickness of the gas barrier layer was changed to 300 nm.

A comparative sealing film 12 was obtained in in a completely similar manner to that “Production of sealing film 1”, except that the gas barrier layer A10 was changed to the above-mentioned gas barrier layer C10.

“Production of Sealing Film 13”

A comparative sealing film 13 was obtained in a completely similar manner to that in “Production of sealing film 1”, except that an ionic liquid was not used.

<<Preparation of Organic Thin Film Electronic Device>>

An organic EL element, which is an organic thin film electronic device, was prepared by using the sealing film of one or more embodiments of the present invention.

[Preparation of Organic EL Element]

(Washing of Glass Substrate)

The glass substrate was washed in a clean room of class 10000 and in a clean booth of class 100, respectively. A detergent for washing semiconductors and ultrapure water (18 MΩ or more, total organic carbon (TOC):lower than 10 ppb) were used as the solvents for the washing, and a ultrasonic washing machine and a UV washing machine were used.

(Formation of First Electrode)

A film of ITO (indium tin oxide (Indium Tin Oxide: ITO)) having a thickness of 150 nm was formed on the glass substrate by a sputtering process, and subjected to patterning by a photolithographic process, whereby a first electrode was formed. The pattern was a pattern having a light emitting surface area of 50 mm square.

(Formation of Hole Transport Layer)

Prior to the application of an application liquid for forming a hole transport layer, the glass substrate on which the first electrode had been formed was subjected to a washing surface modification treatment by using a low pressure mercury lamp having a wavelength of 184.9 nm at an irradiation intensity of 15 mW/cm² and a distance of 10 mm. A charge elimination treatment was conducted by using a static eliminator by a faint X-ray.

An application liquid for forming a hole transport layer shown below was applied onto the first electrode of the glass substrate on which the first electrode had been formed under an environment at 25° C. and a relative humidity of 50% RH by using a spin coater, and drying and thermal treatments were conducted under the following conditions, whereby a hole transport layer was formed. The application liquid for forming a hole transport layer was applied so that the thickness after the drying became 50 nm.

<Preparation of Application Liquid for Forming Hole Transport Layer>

A solution in which polyethylene dioxythiophene/polystyrene sulfonate (PEDOT/PSS, Bytron P AI 4083 manufactured by Bayer) had been diluted with 65% of pure water and 5% of methanol was prepared as an application liquid for forming a hole transport layer.

<Conditions for Drying and Thermal Treatments>

The application liquid for forming a hole transport layer was applied, and the solvents were removed at a height of 100 mm, an ejection wind velocity of 1 m/s, a transversal wind velocity distribution of 5% and a temperature of 100° C. toward the film-formed surface. Subsequently, a thermal treatment of a rear-surface heat transfer system was conducted by using a thermal treatment device at a temperature of 150° C., whereby a hole transport layer was formed.

(Formation of Light-Emitting Layer)

An application liquid for forming a white light-emitting layer shown below was applied by a spin coater onto the hole transport layer formed above under the following conditions, and drying and thermal treatments were conducted under the following conditions, whereby a light-emitting layer was formed. The application liquid for forming a white light-emitting layer was applied so that the thickness after the drying became 40 nm.

<Application Liquid for Forming White Light-Emitting Layer>

An application liquid for forming a white light-emitting layer was prepared by dissolving 1.0 g of the compound represented by the following chemical formula H-A as a host material, 100 mg of the compound represented by the following chemical formula D-A as a dopant material, 0.2 mg of the compound represented by the following chemical formula D-B as a dopant material and 0.2 mg of the compound represented by the following chemical formula D-C as a dopant material in 100 g of toluene.

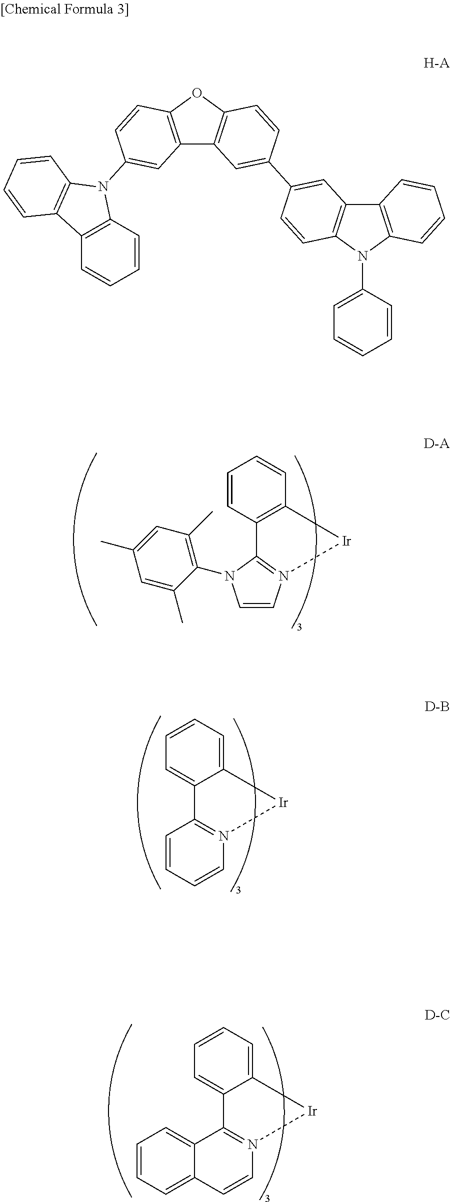

<Conditions for Application>

The application step was conducted under an atmosphere of a nitrogen gas concentration of 99% or more at an application temperature of 25° C.

<Conditions for Drying and Thermal Treatments>

The application liquid for forming a white light-emitting layer was applied, and the solvents were removed at a height of 100 mm, an ejection wind velocity of 1 m/s, a transversal wind velocity distribution of 5% and a temperature of 60° C. toward the film-formed surface. Subsequently, a thermal treatment was conducted at a temperature of 130° C., whereby a light-emitting layer was formed.

(Formation of Electron Transport Layer)

The application liquid for forming an electron transport layer shown below was applied by a spin coater onto the light-emitting layer formed above under the following conditions, and subjected to drying and thermal treatments under the following conditions, whereby an electron transport layer was formed. The application liquid for forming an electron transport layer was applied so that the thickness after the drying became 30 nm.

<Conditions for Application>

The application step was conducted under an atmosphere of a nitrogen gas concentration of 99% or more, and an application temperature of the application liquid for forming an electron transport layer of 25° C.

<Application Liquid for Forming Electron Transport Layer>

For the electron transport layer, an application liquid for forming an electron transport layer was prepared by dissolving the compound represented by the following chemical formula E-A in 2,2,3,3-tetrafluoro-1-propanol to give a 0.5% by mass solution.

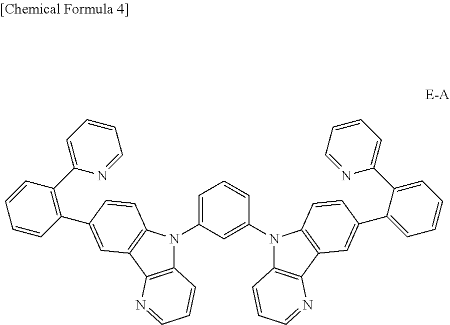 [SMILES: c1ccc(-c2ccccc2-c2ccc3c(c2)c2ncccc2n3-c2cccc(-n3c4ccc(-c5ccccc5-c5ccccn5)cc4c4ncccc43)c2)nc1]

<Conditions for Drying and Thermal Treatments>

The application liquid for forming an electron transport layer was applied, and the solvent was removed at a height of 100 mm, an ejection wind velocity of 1 m/s, a transversal wind velocity distribution of 5% and a temperature of 60° C. toward the film-formed surface. Subsequently, a thermal treatment was conducted at a temperature of 200° C. on a thermal treatment part, whereby an electron transport layer was formed.

(Formation of Electron Injection Layer)

An electron injection layer was formed on the electron transport layer formed above. Firstly, the substrate was put into a pressure reduction chamber, and the pressure was reduced to 5×10⁻⁴ Pa. Cesium fluoride, which had been prepared in a deposition boat made of tantalum in a vacuum chamber in advance, was heated, whereby an electron injection layer having a thickness of 3 nm was formed.

(Formation of Second Electrode)

A second electrode having a thickness of 100 nm was stacked on the part that was on the electron injection layer formed above, except the part that was to be an extraction electrode of the first electrode, by conducting mask pattern film formation so as to give a light emitting surface area of 50 mm square, under a vacuum of 5×10⁻⁴ Pa using aluminum as a material for forming a second electrode, so as to have an extraction electrode, by a deposition process.

(Cutting)

Each laminate in which the layers up to the second electrode had been formed as above was transferred again to a nitrogen atmosphere, and cut into a predetermined size by using ultraviolet laser, whereby an organic EL element was prepared.

(Connection of Electrode Lead)

A flexible printing substrate (base film: polyimide 12.5 μm, rolled copper foil 18 μm, cover lay: polyimide 12.5 μm, surface treatment NiAu plating) was connected to the prepared organic EL element by using an anisotropic electroconductive film DP3232S9 manufactured by Sony Chemical & Information Device Corporation.

Pressure bonding was conducted under pressure bonding conditions of a temperature of 170° C. (ACF temperature measured by separately using a thermocouple: 140° C.), a pressure of 2 MPa and 10 seconds.

(Sealing)

The sealing film of one or more embodiments of the present invention was stored under conditions as substituted for storage of environment temperature/humidity: 40° C./80% RH for 3 days, and the resin layer of the sealing film was vacuum-pressed toward the organic EL element-formed glass substrate in a glove box having an oxygen concentration of 10 ppm or less and a moisture concentration of 10 ppm or less, under conditions of 80° C., under a load of 0.04 MPa, aspiration under a reduced pressure (1×10⁻³ MPa or less) for 20 seconds, and pressing for 20 seconds.

Subsequently, the sealing film was heated in the glove box on a hot plate of 110° C. for 30 minutes, whereby the sealing film of one or more embodiments of the present invention was thermally cured.

<<Evaluation of Organic EL Element>>

The durability was evaluated on the organic EL element prepared above, by evaluating the dark spots after the organic EL element had undergone an accelerated deterioration treatment according to the following method.

[Evaluation of Durability]

(Accelerated Deterioration Treatment)

Each organic EL element prepared above was subjected to an accelerated deterioration treatment for 1,000 hours under an environment at 85° C. and 85% RH, and the following evaluation relating to the dark spots was conducted.

(Evaluation of Dark Spots (DS, Black Points))

An electrical current of 1 mA/cm² was applied on the organic EL element that has undergone the accelerated deterioration treatment, and the organic EL element was allowed to continuously emit light for 24 hours. A part of the panel was enlarged by a 100-fold microscope (MS-804 manufactured by MORITEX Corporation, lens MP-ZE25-200), and photographed. The photographed image was cut into a shape corresponding to a 2 mm square scale, the ratio of the surface area on which dark spots had generated was obtained, and the durability was evaluated according to the following criteria. When the evaluation rank was Δ, the property was judged to be practical, when the rank was ◯, the property was judged to be more practical, and when the rank was ⊙, the property was judged to be a preferable property without any problem.

⊙: The dark spot generation rate is lower than 0.3%,

◯: the dark spot generation rate is 0.3% or more and lower than 1.0%,

Δ: the dark spot generation rate is 1.0% or more and lower than 2.0%,

×: the dark spot generation rate is 2.0% or more and lower than 5.0%,

××: the dark spot generation rate is 5.0% or more.

The constitutions of the sealing films 1 to 13 and the results of the evaluation of the dark spots are shown in the following Table 1.

TABLE 1

| | Gas barrier layer | | | | | | | |
|---|---|---|---|---|---|---|---|---|
| | Layer 1 | | | | Layer 2 | | | |
| | | | Layer | | | | Layer | |
| Sealing | | Formation | thickness | Incorporation | | Formation | thickness | Incorporation |

| film No. | Layer | method | (nm) | of Al | Layer | method | (nm) | of Al |
|---|---|---|---|---|---|---|---|---|
| 1 | Barrier | Application | 300 | — | — | | | |
| | layer A10 | | | | | | | |
| 2 | Barrier | Application | 300 | — | — | | | |
| | layer A10 | | | | | | | |
| 3 | Barrier | Application | 300 | — | — | | | |
| | layer A10 | | | | | | | |
| 4 | Barrier | Application | 150 | — | Barrier | Application | 150 | ◯ |
| | layer A11 | | | | layer A21 | | | |
| 5 | Barrier | Application | 150 | — | Barrier | Application | 150 | ◯ |
| | layer A11 | | | | layer A21 | | | |
| 6 | Barrier | Sputtering | 150 | — | Barrier | Application | 150 | — |
| | layer C11 | | | | layer A11 | | | |
| 7 | Barrier | CVD1 | 150 | — | Barrier | Application | 150 | — |
| | layer C21 | | | | layer A11 | | | |
| 8 | Barrier | CVD1 | 150 | — | Barrier | Application | 150 | ◯ |
| | layer C21 | | | | layer A21 | | | |
| 9 | Barrier | Sputtering | 100 | — | Barrier | Application | 100 | — |
| | layer C12 | | | | layer A12 | | | |
| 10 | Barrier | CVD1 | 100 | — | Barrier | Application | 100 | — |
| | layer C22 | | | | layer A12 | | | |
| 11 | Barrier | CVD2 | 100 | — | Barrier | Application | 100 | — |
| | layer C23 | | | | layer A12 | | | |

| | | | | | |
|---|---|---|---|---|---|
| 12 | Barrier | Sputtering | 300 | — | — |
| | layer C10 | | | | |
| 13 | Barrier | Application | 300 | — | — |
| | layer A10 | | | | |

| | Gas barrier layer | | | | | | |
|---|---|---|---|---|---|---|---|
| | Layer 3 | | | | | | |
| | | | Layer | | | | |
| Sealing | | Formation | thickness | Incorporation | | Evaluation | |
| film No. | Layer | method | (nm) | of Al | Resin layer | of DS | Notes |
| 1 | — | | | | Ionic | Δ | Present |
| | | | | | liquid 1 | | invention |
| 2 | — | | | | Ionic | ◯ | Present |
| | | | | | liquid 2 | | invention |
| 3 | — | | | | Ionic | ◯ | Present |
| | | | | | liquid 3 | | invention |
| 4 | — | | | | Ionic | ◯ | Present |
| | | | | | liquid 1 | | invention |
| 5 | — | | | | Ionic | ⊙ | Present |
| | | | | | liquid 2 | | invention |
| 6 | — | | | | Ionic | Δ | Present |
| | | | | | liquid 1 | | invention |
| 7 | — | | | | Ionic | Δ | Present |
| | | | | | liquid 1 | | invention |
| 8 | — | | | | Ionic | ◯ | Present |
| | | | | | liquid 1 | | invention |
| 9 | Barrier | Application | 100 | ◯ | Ionic | ◯ | Present |
| | layer A22 | | | | liquid 1 | | invention |
| 10 | Barrier | Application | 100 | ◯ | Ionic | ⊙ | Present |
| | layer A22 | | | | liquid 1 | | invention |
| 11 | Barrier | Application | 100 | ◯ | Ionic | ◯ | Present |
| | layer A22 | | | | liquid 1 | | invention |

| | | | | |
|---|---|---|---|---|
| 12 | — | Ionic | X X | Comparative |
| | | liquid 1 | | Example |
| 13 | — | — | X | Comparative |
| | | | | Example |

Ionic liquid 1: N-acetylglycine-1,1-dimethylpyrrolidinium salt
Ionic liquid 2: N-acetylglycine tetrabutylphosphonium salt
Ionic liquid 3: formic acid-1-ethyl-3-methylimidazolium salt

It is understood from Table 1 that the resistance to moisture permeation was not deteriorated even after the accelerated deterioration treatment had been conducted on the sealing film of one or more embodiments of the present invention as compared to that in Comparative Examples, and thus the generation of dark spots (DS) in the organic EL element can be effectively suppressed.

Furthermore, more specifically, it is understood from the results of the sealing films 1 to 3 that N-acetylglycine tetrabutylphosphonium salt and 1-ethyl-3-methylimidazolium formate salt are excellent as ionic liquids against DS.

Furthermore, it is understood that the sealing films 4, 5 and 9 to 11 containing an aluminum compound in the barrier layer are excellent in DS even the ionic liquid 1 is used.

Furthermore, when the sealing films 9 to 11, in which the gas barrier layers were formed by sputtering, CVD1 and CVD2, are compared, it is understood that the sealing film 10, in which the gas barrier layer was formed by a discharging plasma chemical vapor deposition process having a discharging space between a pair of rollers to which an electric field has been applied, exerts an especially excellent result.

Furthermore, when the flexibilities of the sealing films 10 and 11, in which the gas barrier layers had been formed by a CVD1 process and a CVD2 process, were evaluated by the resistances to moisture permeation before and after the following folding test, it was found that the sealing film 10 was also excellent in flexibility since the change in the resistance to moisture permeation before and after the folding test was small, and the carbon atoms had a distribution state satisfying the above-mentioned (i) to (iii) in the layer thickness direction of the gas barrier layer.

<Folding Test>

The sealing film was subjected to 100 times of repetitive bending treatments at an angle of 180° so as to have a curvature of a radius of 10 mm, and the water vapor transmittances (WVTR) before and after the treatment were measured and compared.

### INDUSTRIAL APPLICABILITY

The sealing film of one or more embodiment of the present invention is a sealing film that is excellent in resistance to moisture permeation even it is used after having been stored under a high humidity environment, and thus is preferably used as a sealing material for organic electroluminescent panels (organic EL panels), organic electroluminescent elements (organic EL element), organic photoconversion elements, liquid crystal display elements and the like.

### REFERENCE SIGNS LIST

1 sealing film

1a substrate

1b gas barrier layer

1c resin layer

31 production device

32 sending roller

33,34,35,36 transport roller

39, 40 film formation roller

41 gas supply tube

42 power source for generating plasma

43,44 electric field generator

45 winding roller

100 organic EL element

101 first electrode

101a primer layer

101b electrode layer

103 organic functional layer

103a hole injection layer

103b hole transport layer

103c light-emitting layer

103d electron transport layer

103e electron injection layer

105a second electrode

107 sealing film (substrate+gas barrier layer)

109 resin layer

113 resin substrate (transparent substrate)

113a light extraction surface

115 auxiliary electrode

116 extraction electrode

h emitted light

201 device chamber

202 Xe excimer lamp

203 holder

204 sample stage

205 sample

206 light blocking plate

Although the disclosure has been described with respect to only a limited number of embodiments, those skilled in the art, having benefit of this disclosure, will appreciate that various other embodiments may be devised without departing from the scope of the present invention. Accordingly, the scope of the invention should be limited only by the attached claims.

1.-6. (canceled)

7. A sealing film comprising:
a substrate;
a first gas barrier layer formed on a surface of the substrate; and
a resin layer formed on the surface of the substrate, wherein
the first gas barrier layer is formed by applying an application liquid comprising a polysilazane, drying the application liquid, and performing a modification treatment, and
the resin layer comprises an ionic liquid.

8. The sealing film according to claim 7, wherein the first gas barrier layer further comprises an aluminum compound.

9. The sealing film according to claim 7, wherein the ionic liquid in the resin layer comprises:
an ammonium-based cation or a phosphonium-based cation; and
an N-acylamino acid ion or a carboxylic acid-based anion.

10. The sealing film according to claim 7, further comprising:
a second gas barrier layer formed between the substrate and the first gas barrier layer by a discharging plasma chemical vapor deposition process having a discharging space between a pair of rollers to which an electric field has been applied, and by using a raw material gas comprising an organic silicon compound and an oxygen gas on the surface of the substrate.

11. A method for producing a sealing film, comprising:
forming a first gas barrier layer on a surface of a substrate by applying an application liquid comprising a polysilazane, drying the application liquid, and performing a modification treatment; and
forming a resin layer by applying a resin layer liquid comprising an ionic liquid onto the first gas barrier layer and drying the resin layer liquid.

12. A functional element sealed with the sealing film according to claim 7.

13. The sealing film according to claim 8, wherein the ionic liquid contained in the resin layer comprises:
an ammonium-based cation or a phosphonium-based cation; and
an N-acylamino acid ion or a carboxylic acid-based anion.

14. The sealing film according to claim 8, further comprising:
a second gas barrier layer disposed between the substrate and the gas barrier layer by a discharging plasma chemical vapor deposition process having a discharging space between a pair of rollers to which an electric field has been applied, and by using a raw material gas containing an organic silicon compound and an oxygen gas on the surface of the substrate.

15. The sealing film according to claim 9, further comprising:
a second gas barrier layer disposed between the substrate and the gas barrier layer by a discharging plasma chemical vapor deposition process having a discharging space between a pair of rollers to which an electric field has been applied, and by using a raw material gas containing an organic silicon compound and an oxygen gas on the surface of the substrate.

16. A functional element sealed with the sealing film according to claim 8.

17. A functional element sealed with the sealing film according to claim 9.

18. A functional element sealed with the sealing film according to claim 10.
